(19) United States
(12) Patent Application Publication
(10) Pub. No.: US 2021/0083017 A1
(43) Pub. Date: Mar. 18, 2021

(54) DISPLAY PANEL AND DISPLAY PANEL MANUFACTURING METHOD

(71) Applicant: JOLED Inc., Tokyo (JP)

(72) Inventors: Takahiro KOMATSU, Tokyo (JP); Kosuke MISHIMA, Tokyo (JP); Koyo SAKAMOTO, Tokyo (JP)

(73) Assignee: JOLED Inc., Tokyo (JP)

(21) Appl. No.: 17/017,725

(22) Filed: Sep. 11, 2020

(30) Foreign Application Priority Data
Sep. 13, 2019 (JP) 2019-167004

(51) Int. Cl. H01L 27/32; H01L 51/56; H01L 51/52

(52) U.S. Cl. CPC H01L 27/3218; H01L 51/56; H01L 2251/308; H01L 2251/306; H01L 51/5218

(57) ABSTRACT

A display panel in which pixels each include light-emitting parts are two-dimensionally arranged across a main surface of a substrate. The light-emitting parts each include: a first electrode that is light-reflective; a first functional layer disposed above the first electrode; a light-emitting layer disposed above the first functional layer; a second functional layer disposed above the light-emitting layer and including ytterbium; and a second electrode disposed above the second functional layer and being light-transmissive. At least one of the light-emitting layer and the first functional layer is an applied film. With respect to each pixel, at least one of the light-emitting parts differs from any other of the light-emitting parts in terms of light emission color, and the at least one light-emitting part differs from the any other of the light-emitting parts in terms of film thickness of at least one of the light-emitting layer and the first functional layer.

This application claims priority to Japanese Patent Application No. 2019-167004, filed Sep. 13, 2019, the contents of which are hereby incorporated by reference in their entirety.

### BACKGROUND

### Technical Field

The present disclosure relates to a display panel in which pixels including light-emitting elements such as organic electric-field light-emitting elements (referred to hereinafter as organic EL elements) are two-dimensionally arranged across a main surface of a substrate, and to a method of manufacturing the display panel.

### Description of Related Art

As self-luminous display panels, organic EL display panels in which organic EL elements are arranged in a matrix on a substrate have been recently put to practical use as displays of electrical equipment. The organic EL elements each have a basic structure in which an organic light-emitting layer including an organic light-emitting material is disposed between an electrode pair of an anode and a cathode. When driven, a voltage is applied across the electrode pair (the anode and the cathode), and holes injected to the organic light-emitting layer from the anode and electrons injected to the organic light-emitting layer from the cathode recombine to emit light. Thus, the organic EL elements are current-driven light-emitting elements.

In full-color organic EL display panels, each organic EL element having the above structure forms a red (R), blue (B), or green (G) subpixel and adjacent R, G, and B subpixels combine to form one pixel. Many of such full-color organic EL display panels adopt a so-called optical cavity structure in order to further improve a luminous efficiency in each light emission color (for example, International Publication No. WO2015/194189).

According to the optical cavity structure, a film thickness of an organic layer which is appropriate for increasing the luminous efficiency of the organic EL element of each light emission color depends on wavelength of the light emission color. As the wavelength of the light emission color increases, the film thickness of the organic layers increases. Further, organic layers having different film thicknesses are formed by a wet process such as a printing method, mainly from the viewpoint of manufacturing costs.

Also, an electron injection transport layer is formed by doping an organic material having electron transport properties with Ba having a low work function, thereby improving the electron injection properties and lowering a driving voltage.

### SUMMARY

A display panel pertaining to at least one aspect of the present disclosure is a display panel in which pixels each including light-emitting parts are two-dimensionally arranged across a main surface of a substrate. The light-emitting parts each include: a first electrode that is light-reflective; a first functional layer that is disposed above the first electrode; a light-emitting layer that is disposed above the first functional layer; a second functional layer that is disposed above the light-emitting layer and includes ytterbium; and a second electrode that is disposed above the second functional layer and is light-transmissive. At least one of the light-emitting layer and the first functional layer is an applied film. With respect to each of the pixels, at least one of the light-emitting parts differs from any other of the light-emitting parts in terms of light emission color, and the at least one light-emitting part differs from the any other of the light-emitting parts in terms of film thickness of at least one of the light-emitting layer and the first functional layer.

### BRIEF DESCRIPTION OF THE DRAWINGS

Objects, advantages, and features of the technology pertaining to the present disclosure will become apparent from the following description thereof taken in conjunction with the accompanying drawings, which illustrate at least one embodiment of the technology pertaining to the present disclosure.

FIG. 1 is a block diagram illustrating the overall structure of an organic EL display device pertaining to at least one embodiment of the present disclosure.

FIG. 2 is a schematic enlarged plan view illustrating part of an image display surface of an organic EL display panel of the organic EL display device pertaining to at least one embodiment of the present disclosure.

FIG. 3 is a perspective diagram illustrating a substrate after forming of banks (column banks) and pixel partition layers (row banks) pertaining to at least one embodiment of the present disclosure.

FIG. 4 is a schematic cross-section diagram, taken along a line A-A in FIG. 2, pertaining to at least one embodiment of the present disclosure.

FIG. 5 is a schematic diagram for explaining an optical cavity structure pertaining to at least one embodiment of the present disclosure.

FIG. 6 is a table illustrating examples of material and film thickness of layers of the organic EL display panel pertaining to at least one embodiment of the present disclosure.

FIG. 7A is a graph illustrating variation of a driving voltage with the passage of a driving time with respect to organic EL elements pertaining to at least one embodiment of the present disclosure, and FIG. 7B is a table illustrating results of experiments on a metal dopant of a second functional layer and a driving voltage stability to verify effects by the organic EL elements pertaining to at least one embodiment of the present disclosure.

FIG. 8 is a flowchart illustrating a manufacturing process of the organic EL display panel pertaining to at least one embodiment of the present disclosure.

FIG. 9A to FIG. 9D are partial cross-section diagrams schematically illustrating the manufacturing process of the organic EL display panel pertaining to at least one embodiment of the present disclosure.

FIG. 10A to FIG. 10D are partial cross-section diagrams, continuing from FIG. 9D, schematically illustrating the manufacturing process of the organic EL display panel pertaining to at least one embodiment of the present disclosure.

FIG. 11A and FIG. 11B are partial cross-section diagrams, continuing from FIG. 10D, schematically illustrating the manufacturing process of the organic EL display panel pertaining to at least one embodiment of the present disclosure.

FIG. 12A to FIG. 12D are partial cross-section diagrams, continuing from FIG. 11B, schematically illustrating the manufacturing process of the organic EL display panel pertaining to at least one embodiment of the present disclosure.

FIG. 13A to FIG. 13G are cross-section diagrams schematically illustrating a process of manufacturing a color filter substrate separately pertaining to at least one embodiment of the present disclosure in organic EL display panel manufacturing.

FIG. 14A and FIG. 14B are cross-section diagrams, continuing from FIG. 13G, schematically illustrating the manufacturing process of the organic EL display panel pertaining to at least one embodiment of the present disclosure.

FIG. 15 is a diagram schematically illustrating a layered structure of organic EL elements pertaining to at least one embodiment of the present disclosure.

FIG. 16 is a diagram schematically illustrating a layered structure of organic EL elements pertaining to at least one embodiment of the present disclosure.

FIG. 17 is a diagram schematically illustrating a layered structure of organic EL elements pertaining to at least one embodiment of the present disclosure.

FIG. 18 is a diagram schematically illustrating a layered structure of organic EL elements pertaining to at least one embodiment of the present disclosure.

FIG. 19 is a diagram schematically illustrating a layered structure of organic EL elements pertaining to at least one embodiment of the present disclosure.

FIG. 20 is a schematic cross-section diagram illustrating an organic EL display panel pertaining to at least one embodiment of the present disclosure.

FIG. 21 is a schematic cross-section diagram for describing a problem in a conventional organic EL display panel.

### DETAILED DESCRIPTION

<<Process by which One Aspect of the Present Disclosure was Achieved>>

In the case where an optical cavity structure is adopted as in the above International Publication No. WO2015/194189 (hereinafter, referred to as Patent Literature 1), film thicknesses of organic light-emitting layers, hole injection transport layers, and so on differ between light emission colors, and accordingly amounts of moisture and so on remaining in the layers differ between the light emission colors. Due to this, a deterioration degree of Ba in electron injection transport layers at the initial stage, during storage, and during electric current application differs between the light emission colors.

As a result, a luminance varies between the light emission colors, and thus a color tone of color images to be displayed varies. This might make a viewer to feel that image quality has deteriorated in earlier than expected.

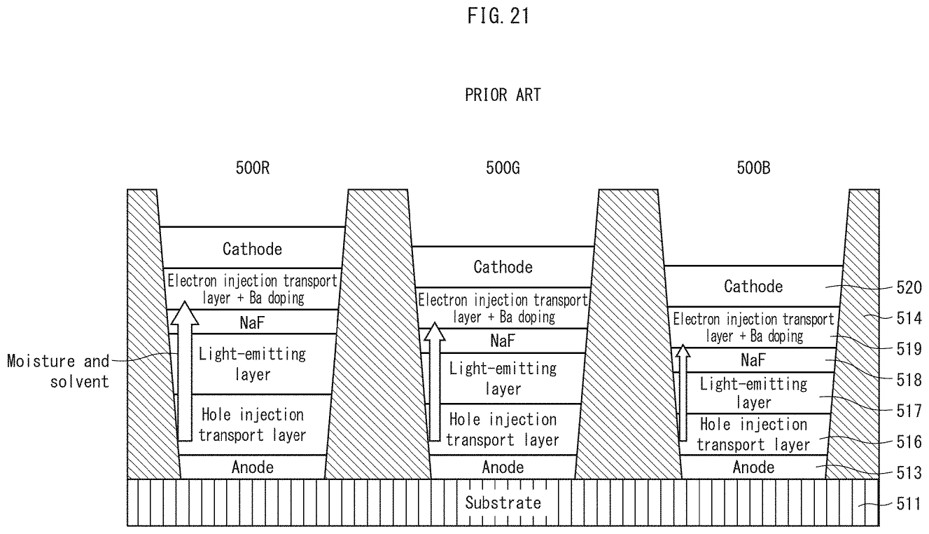

FIG. 21 is a schematic cross-section diagram illustrating a layered structure of an organic EL display panel pertaining to Patent Literature 1 described above. In the figure, reference numerals 500R, 500G, and 500B indicate subpixels emitting light of red (R), green (G), and blue (B) colors, respectively.

The subpixels 500R, 500G, and 500B are partitioned by banks 514 formed above a substrate 511, and each include an organic EL element. Each organic EL element includes an anode 513, a hole injection transport layer 516, an organic light-emitting layer 517, an NaF layer 518, an electron injection transport layer 519, and a cathode 520 which are disposed in this order from the substrate 511.

Further, a sealing layer and so on are layered above the cathodes 520, though not illustrated here.

As illustrated in FIG. 21, the hole injection transport layers 516 and the organic light-emitting layers 517 have respective film thicknesses which increase in the order of the B, G, and R light emission colors as wavelengths increase in this order, and these layers have structures such that luminous efficiency is improved by the optical cavity structure.

To form organic layers having film thicknesses differing between the light emission colors, a wet process by a printing method is often adopted. According to the wet process, it is easy to perform separate application for each light emission color, thereby significantly simplifying a working process and also exhibiting a high use efficiency of materials compared with a dry process. This helps to reduce production costs.

The electron injection transport layers 519 are formed by doping an organic material having electron transport properties with Ba having a low work function. In many cases, there is a large difference between an energy level of the lowest unoccupied molecular orbital (LUMO) of the organic material included in the organic light-emitting layers 517 and a Fermi level of a material of the cathode, and this exhibits unsatisfactory electron injection properties. In view of this, by doping an organic material with Ba, which is a metal material having a low work function, the electron injection properties are improved, thereby facilitating transport of electrons from the cathodes 520 to the organic light-emitting layers 517 and helping to reduce a driving voltage.

By the way, the hole injection transport layers 516 and/or the organic light-emitting layers 517 formed by the wet process are dried by baking or the like such that moisture, solvent, and so on (hereinafter, referred to collectively as moisture etc.) inside the layers are removed. Unfortunately, complete removal of the moisture etc. is difficult, and a slight amount of the moisture etc. always remains inside the layers. This moisture etc. diffuses into even the electron injection transport layers 519, which are upper layers of the hole injection transport layers 516 and the organic light-emitting layers 517, as a driving time of the organic EL elements passes by. Ba, with which is doped for forming the electron injection transport layer 519, is chemically active, and accordingly reacts with the moisture etc. to cause the electron injection properties to deteriorate thus to shorten the operating life.

According to Patent Literature 1 described above, in view of this, the NaF layers 518 are formed, as intermediate layers, between the organic light-emitting layers 517 and the electron injection transport layers 519. A fluoride of an alkali metal such as Na or an alkaline earth metal has properties of blocking moisture etc., and suppresses penetration of moisture etc. from the organic light-emitting layers 517 and so on to the electron injection transport layers 519, thereby contributing to an increase of an operating life of organic EL display panels.

Meanwhile, the NaF layers 518 have high insulating properties. Accordingly, parts of the NaF layers 518 which is on the side of the second functional layer 19 are reduced by Ba of the electron injection transport layer 519 such that the parts dissociate into Na and F. This exhibits excellent electron injection properties. In the case where the film thickness of the NaF layers 518 is increased in order to improve the properties of blocking moisture etc., only a small reduction action of the upper layers exerts on especially lower parts of the intermediate layers, and thus the driving voltage increases. This insufficiently achieves the purpose of improving the luminous efficiency.

Thus, the film thickness of the NaF layers 518 has a certain upper limit, and the properties of blocking moisture etc. of the NaF layers 518 also have a limit. In addition, since the banks 514 typically include a resin material, moisture etc. might pass through the inside of the resin material to reach the electron injection transport layer 519.

If an optical cavity structure is not adopted and the film thicknesses of the organic light-emitting layers 517 and the hole injection transport layers 516 are set to be uniform among the light emission colors, an amount of moisture etc. remaining in these organic layers is also substantially equal among the light emission colors. When such moisture etc. penetrates through the NaF layers 518 and the banks 514 to react with Ba of the electron injection transport layers 519, a luminous deterioration amount does not greatly differ between the light emission colors. This only makes a viewer to feel a screen has become a little dark. The viewer is unlikely to visually confirm a variation of color tone on a display screen and thus unlikely to feel the image quality has deteriorated.

However, in the case where an optical cavity structure is adopted and the hole injection transport layer 516 and the organic light-emitting layers 517 are formed so as to have film thicknesses differing between the R, G, and B colors, as the film thickness increases, a larger amount of moisture etc. remains inside the layers and thus reaches the electron injection transport layers 519 via the NaF layers 518 and the banks 514. Thus, the deterioration degree of the electron injection properties of Ba increases in the order of the B, G, and R colors, and this causes a difference in deterioration amount of luminance. Thus, reproduced color images have variation in color tone, and this makes a user to easily feel deterioration in image quality early and thus might shorten the product operating life.

Such a problem might occur not only in organic EL display panels using organic EL elements as light-emitting elements but also in display panels typically including self-luminous elements and including organic functional layers formed by a wet process to construct an optical cavity structure such as quantum dot display panels including light-emitting layers formed from quantum dot light-emitting diodes (QLEDs).

In order to solve the above problem, the present inventors earnestly conducted researches for seeking a display panel with a prolonged product operating life while adopting a wet process to reduce costs, adopting an optical cavity structure to improve a luminous efficiency, and suppressing early variation in color tone. As a result, the present inventors achieved at least one aspect of the present disclosure.

<<Outline of at Least One Aspect of the Present Disclosure>>

A display panel pertaining to at least one aspect of the present disclosure is a display panel in which pixels each including light-emitting parts are two-dimensionally arranged across a main surface of a substrate. The light-emitting parts each include: a first electrode that is light-reflective; a first functional layer that is disposed above the first electrode; a light-emitting layer that is disposed above the first functional layer; a second functional layer that is disposed above the light-emitting layer and includes ytterbium; and a second electrode that is disposed above the second functional layer and is light-transmissive. At least one of the light-emitting layer and the first functional layer is an applied film. With respect to each of the pixels, at least one of the light-emitting parts differs from any other of the light-emitting parts in terms of light emission color, and the at least one light-emitting part differs from the any other of the light-emitting parts in terms of film thickness of at least one of the light-emitting layer and the first functional layer.

According to this aspect, at least one of the light-emitting layer and the first functional layer is a layer formed by a wet process to construct an optical cavity structure, thereby achieving both a process cost reduction and a luminous efficiency improvement, and obtaining the second functional layer doped with ytterbium. Ytterbium is a metal having a low work function but is chemically stable. Compared with Ba and so on, ytterbium has a low reactivity with moisture etc., and accordingly electron injection properties are unlikely to deteriorate. For this reason, the above aspect helps to provide a display panel that achieves both a process cost reduction and a luminous efficiency improvement by constructing an optical cavity structure using the wet process and also has a less luminance variation between the light emission colors thus to have a long product operating life.

According to the display panel pertaining to at least one aspect of the present disclosure, the light-emitting parts each further include an intermediate layer that is disposed between the light-emitting layer and the second functional layer, and includes a fluoride of a metal selected from alkali metals or alkaline earth metals.

Also, according to the display panel pertaining to at least one aspect of the present disclosure, the light-emitting parts each further include an intermediate layer that is disposed between the light-emitting layer and the second functional layer, and is a single ytterbium layer.

Deposition of the intermediate layer between the light-emitting layer and the second functional layer helps to suppress diffusion of moisture etc. remaining in the first functional layer including the applied film to the second functional layer, and suppress deterioration of ytterbium which is a metal dopant, thereby resulting in a less luminance variation between the light emission colors.

Also, according to the display panel pertaining to at least one aspect of the present disclosure, the second functional layer includes an organic material doped with ytterbium.

Also, according to the display panel pertaining to at least one aspect of the present disclosure, a doping concentration of the ytterbium ranges from 3 wt % to 60 wt %.

Setting the doping concentration of the ytterbium to range from 3 wt % to 60 wt % achieves necessary electron injection properties, and also avoids a decrease in light-transmissivity of the second functional layer and thus avoids a luminous efficiency deterioration. Also, since the second functional layer is formed by doping an organic material with a necessary amount of ytterbium, the film thickness of the second functional layer is increased, thereby increasing a degree of freedom in designing optical cavity structure.

Also, according to the display panel pertaining to at least one aspect of the present disclosure, the second functional layer is a single ytterbium layer.

According to this aspect, since the second functional layer is formed from only ytterbium, a manufacturing process is easy and stable electron injection properties are achieved.

Also, according to the display panel pertaining to at least one aspect of the present disclosure, the second functional layer includes ytterbium and a fluoride of a metal selected from alkali metals or alkaline earth metals.

According to this aspect, since the second functional layer, which has both properties of blocking moisture etc. which are exhibited by a fluoride of a metal selected from alkali metals or alkaline earth metals and electron injection properties exhibited by ytterbium, is obtained, no intermediate layer needs to be provided separately.

Also, according to the display panel pertaining to at least one aspect of the present disclosure, the light-emitting parts each further include a light-transmissive and electrically-conductive film that is disposed between the second functional layer and the second electrode so as to be in contact with the second functional layer, and includes inorganic oxide. Also, according to the display panel pertaining to at least one aspect of the present disclosure, the light-transmissive and electrically-conductive film is preferably an indium tin oxide (ITO) film or an indium zinc oxide (IZO) film.

This aspect exhibits an effect of a light transmittance improvement owing to oxidization of part of Yb included in the second functional layer in manufacturing a display panel. Also, adjustment of the film thickness of the light-transmissive and electrically-conductive film facilitates construction of an optical cavity structure. Especially an ITO film and an IZO film have an excellent electrical conductivity, and accordingly do not hinder electron injection properties.

Also, according to the display panel pertaining to at least one aspect of the present disclosure, the first electrode is a light-reflective anode, and the second electrode is a light-semitransmissive cathode.

This aspect helps to provide a display panel of a top-emission type including an optical cavity structure having a further excellent luminous efficiency. In the display panel of the top-emission type, drive circuits including TFTs and so on are not disposed in a light emission direction such that an aperture ratio in each light-emitting part increases and thus an excellent luminous efficiency is exhibited.

Also, a display panel manufacturing method pertaining to at least one aspect of the present disclosure is a method of manufacturing a display panel in which pixels each including light-emitting parts are two-dimensionally arranged across a main surface of a substrate. The method includes, for each of the light-emitting parts: forming a first electrode above the substrate; forming a first functional layer above the first electrode; forming a light-emitting layer above the first functional layer; forming a second functional layer above the light-emitting layer; and forming a second electrode above the second functional layer. One of the first electrode and the second electrode is a light-reflective electrode, and the other is a light-transmissive electrode. Out of the first functional layer and the second functional layer, one functional layer that is disposed between the light-reflective electrode and the light-emitting layer includes ytterbium. At least one of the light-emitting layer and the other functional layer out of the first functional layer and the second functional layer is formed by an application method. With respect to each of the pixels, at least one of the light-emitting parts differs from any other of the light-emitting parts in terms of light emission color, and the at least one light-emitting part differs from the any other of the light-emitting parts in terms of film thickness of at least one of the light-emitting layer and the other functional layer out of the first functional layer and the second functional layer.

This aspect helps to manufacture a display panel exhibiting an excellent luminous efficiency, displaying high-quality images, and having a long operating life.

Note that in at least one embodiment of the present disclosure above, the term “above” does not indicate an upper direction (upward in the vertical direction) in an absolute spatial awareness, but is defined by a relative relationship in a layered structure of the light-emitting part. Specifically, a direction that is perpendicular to the main surface of the substrate of the light-emitting part and is toward the second electrode from the first electrode is defined as an upper direction. In addition, for example an expression “above a first electrode” indicates not only a region in direct contact with the first electrode but also an upper region over the first electrode via a laminate.

### Embodiments

The following describes a display panel pertaining to at least one aspect of the present disclosure by using an example of an organic EL display panel, with reference to the drawings. Note that the drawings may be schematic, and are not necessarily to scale.

1. Overall Structure of Organic EL Display Device 1

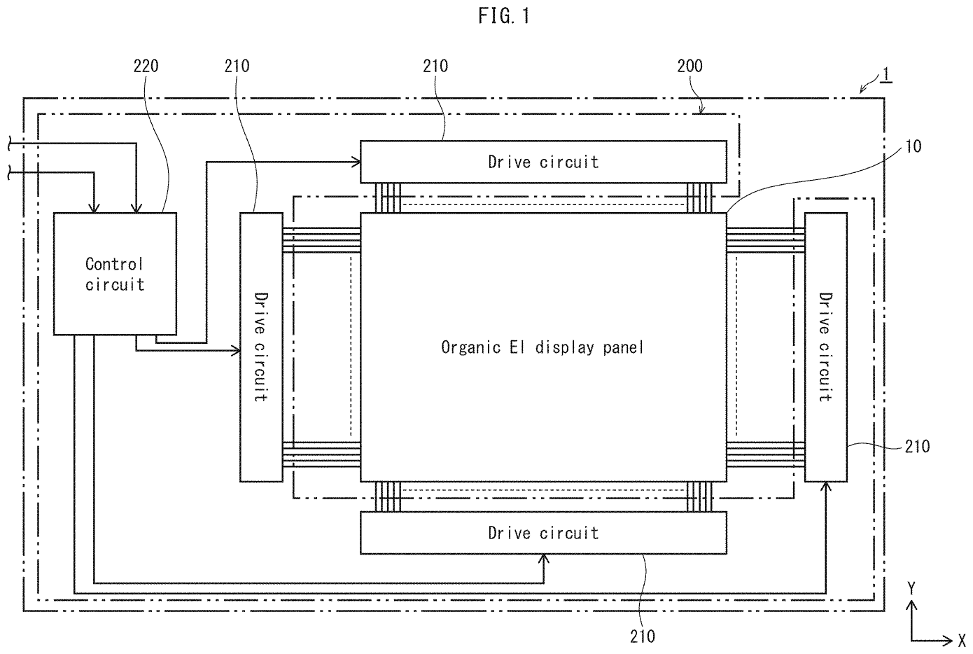

FIG. 1 a block diagram illustrating the overall structure of an organic EL display device 1. The organic EL display device 1 is a display device which is used for example for a television, a personal computer, a mobile terminal, or a display for business purposes such as an electronic signboard and a large screen for a commercial facility.

The organic EL display device 1 includes an organic EL display panel 10 (hereinafter, referred to simply as display panel 10) and a drive controller 200 which is electrically connected to the display panel 10.

According to the present embodiment, the display panel 10 is a top emission type display panel, a top surface of which is a rectangular image display surface. In the display panel 10, a plurality of organic EL elements (not illustrated) are arranged across the image display surface, and an image is displayed by combining light emission of the organic EL elements. As an example, the display panel 10 employs an active matrix system.

The drive controller 200 includes drive circuits 210 connected to the display panel 10 and a control circuit 220 connected to an external device such as a computer or a receiving device such as an antenna. The drive circuits 210 include power supply circuits for supplying electric power to the organic EL elements, signal circuits for applying a voltage signal for controlling the electric power supplied to the organic EL elements, a scanning circuit for switching a position to which the voltage signal is applied at regular intervals, and the like.

The control circuit 220 controls operations of the drive circuits 210 in accordance with data including image information input from the external device or the receiving device.

In FIG. 1, as an example, four of the drive circuits 210 are disposed around the display panel 10, but the structure of the drive controller 200 is not limited to this example, and the number and position of the drive circuits 210 may be modified as appropriate. For the sake of explanation, as illustrated in FIG. 1, a direction along a long side of a top surface of the display panel 10 is referred to as X direction and a direction along a short side of the top surface of the display panel 10 is referred to as Y direction.

2. Structure of Display Panel 10

(A) Plan View Structure

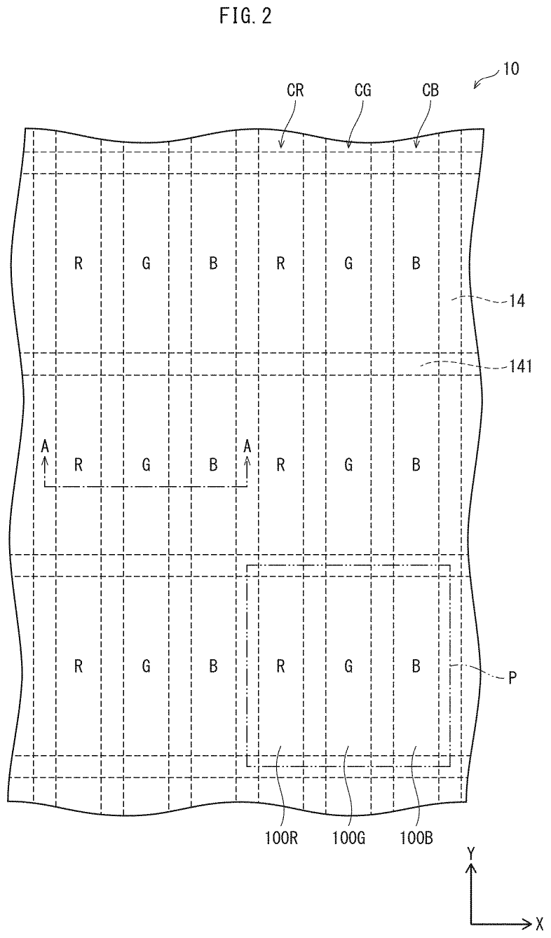

FIG. 2 is a schematic enlarged plan view illustrating part of the image display surface of the display panel 10. According to the display panel 10, as an example, subpixels 100R, 100G, and 100B are arranged in a matrix. In the subpixels 100R, 100G, and 100B, organic EL elements (light-emitting parts) which respectively emit light of red (R), green (G), and blue (B) colors (hereinafter, also referred to simply as R, G, and B) are arranged. The subpixels 100R, 100G, and 100B are lined up alternating in the X direction (row direction), and a set of the subpixels 100R, 100G, and 100B in the X direction constitute one pixel P. Through combining gradation control of luminance of the subpixels 100R, 100G, and 100B, full color is possible.

In addition, in the Y direction (column direction), the subpixels 100R, 100G, and 100B are arranged to form subpixel columns CR, CG, and CB, respectively, in which only the corresponding color of subpixels are present. As a result, across the display panel 10, the pixels P are arranged in a matrix along the X direction and the Y direction, and an image is displayed on the image display surface through a combination of colors of light emitted by the pixels P.

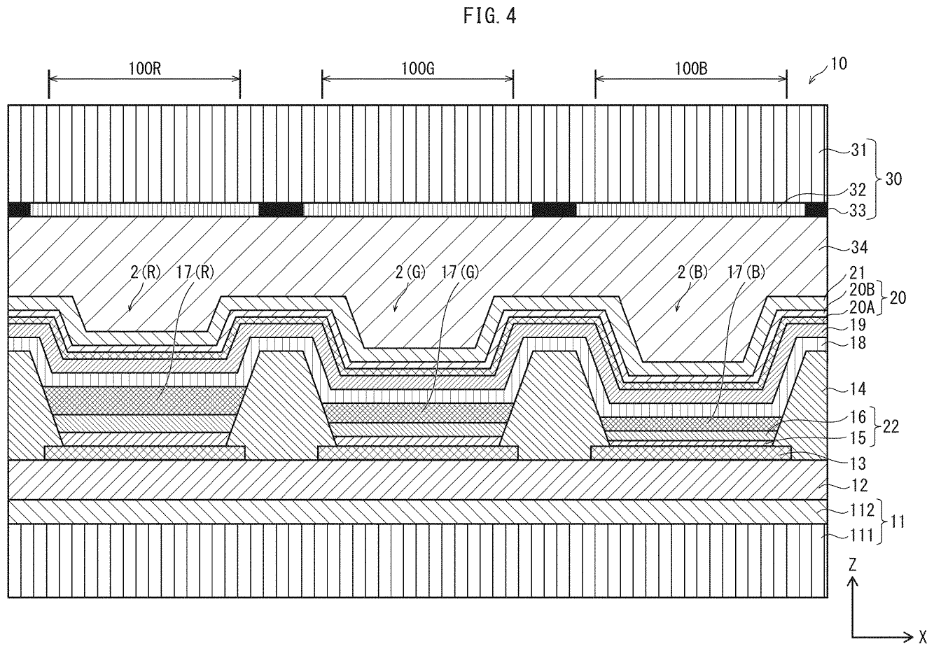

In the subpixels 100R, 100G, and 100B, the organic EL elements 2(R), 2(G), and 2(B), which respectively emit light of the R, G, and B colors, are respectively arranged (see FIG. 4).

Respective ranges of the subpixels 100R, 100G, and 100B are defined by banks (column banks) 14 and pixel partition layers (row banks) 141.

The display panel 10 pertaining to the present embodiment employs a so-called line bank structure.

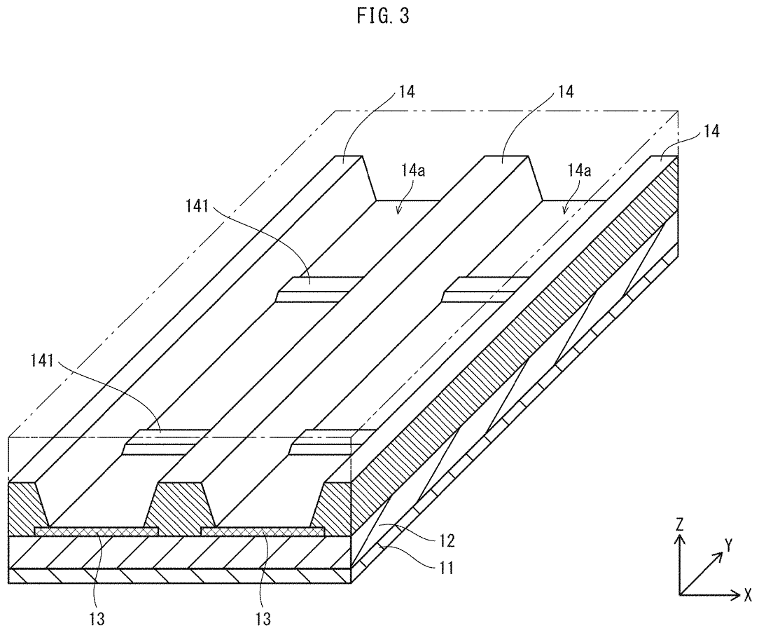

FIG. 3 is a partial perspective diagram of the display panel 10 pertaining to at least one embodiment for explaining how the banks 14 and the pixel partition layers 141 are formed. As illustrated in the figure, the pixel partition layers 141 have a height sufficiently lower than the banks 14. As described later, when organic light-emitting layers 17 and so on are formed by a printing method, liquid surfaces of ink have a height higher than the pixel partition layers 141. This allows the ink to flow in the column direction (Y direction) in order for the liquid surfaces of the ink to be levelled, thereby making variation of film thicknesses in the column direction smaller.

The subpixel columns CR, CG, and CB are partitioned by the banks 14 at intervals in the X direction, and in each of the subpixel columns CR, CG, and CB, the subpixels 100R, 100G, or 100B therein share a continuous organic light-emitting layer.

However, in each of the subpixel columns CR, CG, and CB, the pixel partition layers 141 are disposed at intervals in the Y direction to insulate the subpixels 100R, 100G, and 100B from each other, such that each of the subpixels 100R, 100G, and 100B can emit light independently.

The banks 14 and the pixel partition layers 141 are indicated by dotted lines in FIG. 2. This is because the banks 14 and the pixel partition layers 141 are not exposed on the surface of the image display surface and are disposed inside the image display surface.

(B) Cross-Section Structure

FIG. 4 is a schematic cross-section diagram taken along a line A-A in FIG. 2.

The display panel 10 includes pixels which are each composed of three subpixels each emitting light of a different one of the R, G, and B colors. The three subpixels, namely the subpixels 100R, 100G, and 100B are respectively composed of organic EL elements 2(R), 2(G), and 2(B) emitting light of a corresponding color.

The organic EL elements 2(R), 2(G), and 2(B), which respectively emit light of the R, G, and B colors, basically have the same structure, and thus are referred collectively to as organic EL elements 2 when they are not distinguished from one another.

As illustrated in FIG. 4, the display panel 10 includes a substrate 11, an interlayer insulating layer 12, pixel electrodes (anodes) 13, banks 14, first functional layers 22 (hole injection layers 15 and hole transport layers 16), organic light-emitting layers 17, an intermediate layer 18, a second functional layer 19, a counter electrode (cathode) 20, a sealing layer 21, and a color filter (CF) substrate 30.

(1) Substrate

The substrate 11 includes a base material 111 which is an insulating material and a thin film transistor (TFT) layer 112. The TFT layer 112 has a driving circuit formed therein for each subpixel. The base material 111 is for example a glass substrate, a quartz substrate, a silicon substrate, or a metal substrate including molybdenum sulfide, copper, zinc, aluminum, stainless, magnesium, iron, nickel, gold, and silver, a semiconductor substrate including gallium arsenide, or a plastic substrate.

A plastic substrate is usable to form a flexible display panel. Either thermoplastic resin or thermosetting resin is usable as material of the plastic substrate. The plastic material may be for example a laminate of any one type or any two or more types of the following materials, including polyethylene, polypropylene, polyamide, polyimide (PI), polycarbonate, acrylic resin, polyethylene terephthalate (PET), polybutylene terephthalate, polyacetal, other fluororesin, thermoplastic elastomer such as styrene elastomer, polyolefin elastomer, polyvinyl chloride elastomer, polyurethane elastomer, fluorine rubber elastomer, and chlorinated polyethylene elastomer, epoxy resin, unsaturated polyester, silicone resin, polyurethane, or copolymer, blend, polymer alloy or the like mainly including such a material described above.

(2) Interlayer Insulating Layer

The interlayer insulating layer 12 is formed on the substrate 11. The interlayer insulating layer 12 includes a resin material and is for flattening irregularities in a top surface of the TFT layer 112. The resin material is for example a positive photosensitive material. Examples of the photosensitive material include acrylic resin, polyimide resin, siloxane resin, and phenolic resin. Also, although not illustrated in the cross-section in FIG. 4, the interlayer insulating layer 12 has a contact hole provided therein for each subpixel.

(3) Pixel Electrodes (First Electrodes)

The pixel electrodes 13 include metal layers including a light-reflective metal material, and are formed on the interlayer insulating layer 12. The pixel electrode 13 is formed for each subpixel, and is electrically connected with the TFT layer 112 via a contact hole (not illustrated).

In the present embodiment, the pixel electrode 13 functions as an anode.

Specific examples of the light-reflective metal material include silver (Ag), aluminum (Al), alloy of aluminum, molybdenum (Mo), alloy of silver, palladium, and copper (APC), alloy of silver, rubidium, and gold (ARA), alloy of molybdenum and chromium (MoCr), alloy of molybdenum and tungsten (MoW), and alloy of nickel and chromium (NiCr).

In at least one embodiment, the pixel electrodes 13 are single metal layers. In at least one embodiment, the pixel electrodes 13 have a layered structure including a metal oxide layer such as an indium tin oxide (ITO) layer and an indium zinc oxide (IZO) layer layered on a metal layer.

(4) Banks and Pixel Partition Layers

The banks 14 partition the pixel electrodes 13 corresponding to the subpixels on the substrate 11 into columns in the X direction (see FIG. 2), and each have a line bank shape extending in the Y direction between the subpixel columns CR, CG, and CB in the X direction.

An electrically-insulating material is used for the banks 14. Specific examples of the electrically-insulating material include an insulating organic material such as acrylic resin, polyimide resin, novolac resin, and phenolic resin.

In the case where the organic light-emitting layers 17 are formed by an application method, the banks 14 function as a structure for preventing an ink mixture between subpixels in each pixel.

From the viewpoint of workability, in at least one embodiment, when a resin material is used for the banks 14, a photosensitive resin material is used. Photosensitivity of the resin material may be either positive or negative.

In at least one embodiment, the banks 14 are resistant to organic solvents and heat. Also, in at least one embodiment, the banks 14 have liquid-repellent surfaces in order to suppress an ink overflow.

Where the pixel electrodes 13 are not formed, bottom surfaces of the banks 14 are in contact with a top surface of the interlayer insulating layer 12.

The pixel partition layers 141 include an electrically-insulating material, and cover end parts in the Y direction (FIG. 2) of the pixel electrodes 13 in each sub pixel column, partitioning the pixel electrodes 13 in the Y direction.

Film thickness of the pixel partition layers 141 is set to be slightly larger than film thickness of the pixel electrodes 13 but to be smaller than film thickness of the organic light-emitting layers 17 including their top surfaces. Thus, the organic light-emitting layers 17 in the subpixel columns CR, CG, and CB are not partitioned by the pixel partition layers 141, and accordingly flow of ink is not disturbed when forming the organic light-emitting layers 17. This facilitates the film thickness of each of the organic light-emitting layers 17 to be uniform within the corresponding subpixel column.

With the structure described above, the pixel partition layers 141 improve electrical insulation between the pixel electrodes 13 in the Y direction and also have functions of suppressing discontinuity of the organic light-emitting layers 17 within any given one of the subpixel columns CR, CG, and CB, improving electrical insulation between the pixel electrodes 13 and the counter electrode 20, and so on.

Specific examples of the electrically-insulating material used for the pixel partition layers 141 include a resin material exemplified as the material of the banks 14 and an inorganic material.

(5) First Functional Layers

In the present embodiment, the first functional layers 22 each include two layers, namely, the hole injection layer 15 and the hole transport layer 16.

(5-1) The hole injection layers 15 are provided on the pixel electrodes 13 in order to promote injection of holes from the pixel electrodes 13 to the organic light-emitting layers 17. In the present embodiment, to form the hole injection layers 15 by a wet process, the hole injection layers 15 mainly include an electrically-conductive polymer material such as poly(3,4-ethylenedioxythiophene) polystyrene sulfonate (PEDOT/PSS), an oligomer material, or a low-molecular material.

(5-2) Hole Transport Layers

The hole transport layers 16 have a function of transporting holes injected from the hole injection layers 15 to the organic light-emitting layers 17. The hole transport layers 16 are formed by a wet process using for example a high-molecular compound having no hydrophilic group such as polyfluorene, polyfluorene derivative, polyallylamine, and polyallylamine derivative, or a low-molecular compound having no hydrophilic group and including a similar material.

(6) Organic Light-Emitting Layers

The organic light-emitting layers 17 are formed inside the openings 14a (FIG. 3), and each have a function of emitting light of R, G, or B color owing to recombination of holes and electrons. In particular, when it is necessary to specify the light emission color for explanation, the organic light-emitting layers 17 are referred to as the organic light-emitting layers 17(R), 17(G), and 17(B) separately.

Publicly-known materials are usable for a material of the light-emitting layers 17.

Specific examples of the material of the organic light-emitting layers 17 include phosphor such as oxinoid compound, perylene compound, coumarin compound, azacoumarin compound, oxazole compound, oxadiazole compound, perinone compound, pyrrolopyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylenepyran compound, dicyanomethylenethiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, and metal complex of 8-hydroxyquinoline compound, metal complex of 2-bipyridine compound, complex of a Schiff base and group III metal, oxine metal complex, and rare earth complex.

(7) Intermediate Layer

The intermediate layer 18 has a function of suppressing movement of moisture etc. from the organic layers provided thereunder to the second functional layer 19, and a function of transporting electrons from the counter electrode 20 to the organic light-emitting layers 17.

In the present embodiment, the intermediate layer 18 includes sodium fluoride (NaF). NaF has a low moisture permeability and has waterproofing properties. Contact of NaF with a reducing material (Yb in the present embodiment) causes contact parts of NaF to dissociate into Na and F, thereby obtaining excellent electron injection properties. In at least one embodiment, the intermediate layer 18 includes a fluoride of a metal selected from other alkali metals or alkaline earth metals (for example, Li).

(8) Second Functional Layer

The second functional layer 19 has a function of injecting and transporting electrons supplied from the counter electrode 20 toward the organic light-emitting layers 17. In the present embodiment, the second functional layer 19 includes an organic material, in particular, an organic material having electron transport properties, doped with ytterbium (Yb).

This structure helps to stabilize electron injection properties of the second functional layer 19. Accordingly, when the hole injection layers 15, the hole transport layers 16, and/or the organic light-emitting layers 17 are formed by a wet process so as to have different film thicknesses between the light emission colors in order to construct an optical cavity structure, the electron injection properties are not influenced greatly. This avoids a color tone variation caused by a difference in degree of deterioration between the light emission colors, and thus makes a viewer not to feel the operating life is short. The details will be described later.

The organic material (host material) having electron transport properties is for example a π-electron low molecular organic material such as oxadiazole derivative (OXD), triazole derivative (TAZ), and phenanthroline derivative (BCP, Bphen), but is not limited to these.

(9) Counter Electrode (Second Electrode)

The counter electrode 20 includes a light-transmissive and electrically-conductive material, and is formed on the second functional layer 19. The counter electrode 20 functions as a cathode.

In the present embodiment, the counter electrode 20 has a two-layer structure and is formed by layering a metal thin film 20B on a light-transmissive and electrically-conductive film 20A including metal oxide such as ITO or IZO.

In at least one embodiment, to obtain an optical cavity structure further effectively, the metal thin film 20B of the counter electrode 20 includes at least one material selected from the group consisting of aluminum, magnesium, silver, aluminum-lithium alloy, magnesium-silver alloy, and the like, and has a half mirror structure (light-semitransmissivity). In at least one embodiment, the metal thin film 20B in this case has a film thickness from 5 nm to 30 nm.

Also, adjustment of a film thickness of the light-transmissive and electrically-conductive film 20A helps to set an optical distance between the organic light-emitting layers 17 and a reflective surface of the metal thin film 20B to an appropriate length, thereby obtaining an effective optical cavity structure. In at least one embodiment, a light-transmissive and electrically-conductive film including for example ITO or IZO is formed on the counter electrode 20, thereby adjusting chromaticity and viewing angle.

(10) Sealing Layer

The sealing layer 21 is provided for preventing the metal thin film 20B of the counter electrode 20 and organic layers including the IZO film 20A, the hole transport layers 16, the organic light-emitting layers 17, and the second functional layer 19 from being exposed to moisture, air, and so on and thus from being deteriorated.

The sealing layer 21 for example includes a light-transmissive material such as silicon nitride (SiN) and silicon oxynitride (SiON).

(11) CF Substrate

The CF substrate 30 is attached onto the sealing layer 21 via a joining layer 34. The CF substrate 30 includes color filter layers 32 for correcting chromaticity of light emitted from the organic EL elements 2. The CF substrate 30 helps to further protect the hole transport layers 16, the organic light-emitting layers 17, the second functional layer 19, and so on against external moisture, air, and so on.

3. Principle of Optical Cavity Structure and Examples of Film Thickness in Organic EL Elements

As described above, in at least one embodiment, an optical cavity structure is constructed in order to improve the luminous efficiency of the organic EL elements 2.

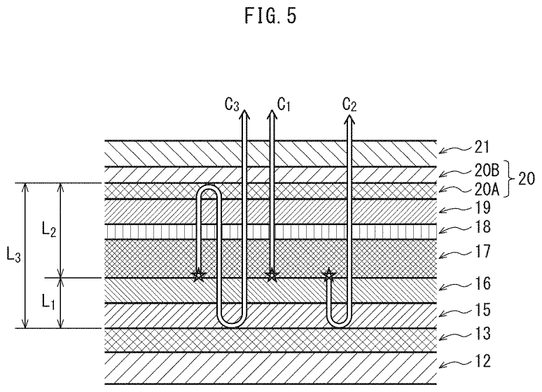

FIG. 5 is a schematic diagram for explaining optical interference in an optical cavity structure of the organic EL elements 2. An optical cavity structure is formed between an interface of the pixel electrodes 13 with the hole injection layers 15 and an interface between the metal thin film 20B and the light-transmissive and electrically-conductive film 20A which are included in the counter electrode 20.

Note that the explanation is provided on the figure based on the assumption that a point of light emission owing to recombination of holes and electrons is near an interface between the organic light-emitting layers 17 and the hole transport layers 16.

In FIG. 5, an optical path C₁ is an optical path along which light emitted from the organic light-emitting layers 17 toward the counter electrode 20 directly transmits through the counter electrode 20 without being reflected.

An optical path C₂ is an optical path along which light emitted from the organic light-emitting layers 17 toward the pixel electrodes 13 is reflected by the pixel electrodes 13, and transmits through the counter electrode 20 via the organic light-emitting layers 17.

An optical path C₃ is an optical path along which light emitted from the organic light-emitting layers 17 toward the counter electrode 20 is reflected by the metal thin film 20B (which is light-semitransmissive) of the counter electrode 20, is further reflected by the pixel electrodes 13, and then transmits through the counter electrode 20 via the organic light-emitting layers 17.

In the optical cavity structure, respective optical distances of the optical paths C₁, C₂, and C₃ are set such that resonance occurs among light emitted along these optical paths. Here, the optical distance of the optical path is the sum of products of film thickness and refractive index in each of the layers through which light transmits. Since the wavelength differs between the light emission colors, the respective film thicknesses of the hole injection layers 15, the hole transport layers 16, the organic light-emitting layers 17, the second functional layer 19, the light-transmissive and electrically-conductive film 20A and so on are determined according to the wavelength.

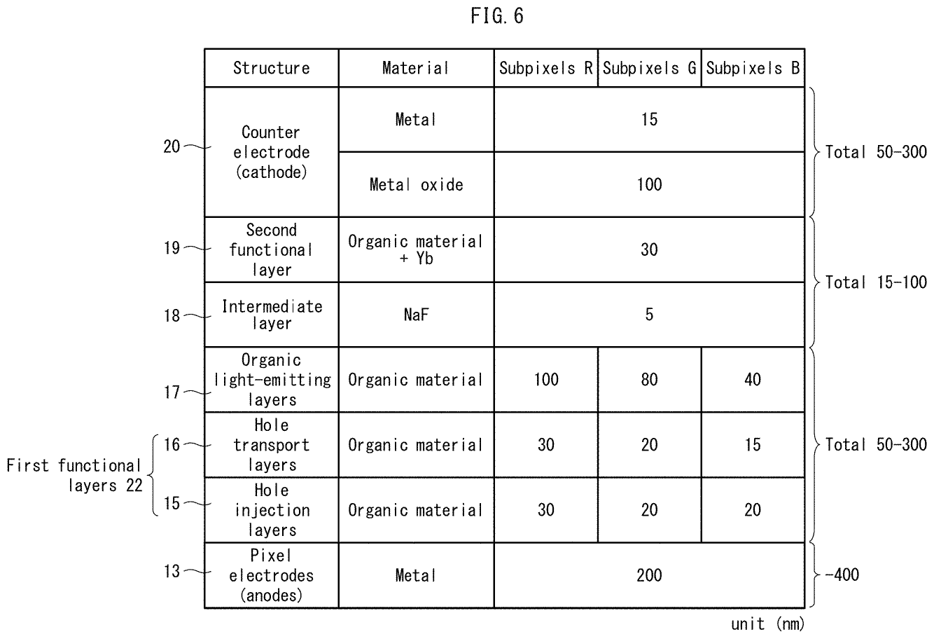

FIG. 6 is a table illustrating a layered structure including every layer from the pixel electrodes 13 to the counter electrode 20 in the organic EL elements 2 pertaining to the present embodiment and specific examples of film thickness of each layer expressed in nm. Numerical values on the right outside the table indicate that a settable range of the total film thickness. For example, the total film thickness of the hole injection layers 15, the hole transport layers 16, and the organic light-emitting layers 17 is indicated to be settable within a range of 50 nm to 300 nm.

Note that the film thicknesses illustrated in the table in FIG. 6 are just examples, and are not limited to these values. A person skilled in the art would appropriately design the film thicknesses according to the specifications of organic EL elements, refractive indexes of materials to be used, and so on.

4. Assessment Test

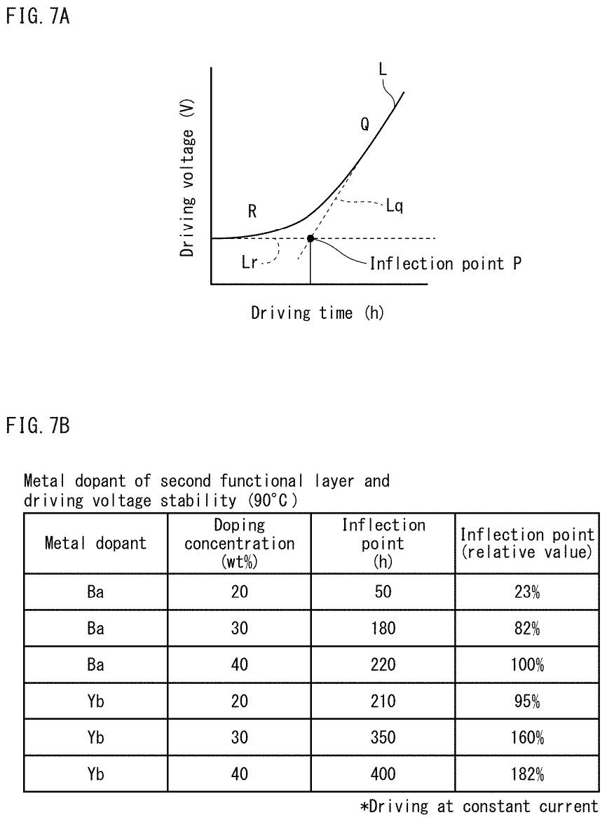

FIG. 7A is a graph illustrating a typical relationship between a driving time (h) of the organic EL elements and a voltage to be applied (hereinafter, referred to as driving voltage) (V) which is necessary to perform control (constant current control) to supply the organic EL elements with a constant electric current.

In the graph of FIG. 7A, a horizontal axis indicates the driving time, a vertical axis indicates the driving voltage, and a curve L indicates variation of the driving voltage with the passage of the driving time. As illustrated in the figure, the driving voltage V gradually varied at low values at the driving beginning (part R), but rapidly rose after a certain time has passed by (part Q).

Here, regarding an approximate straight-line Lr in the part R at the beginning of driving (beginning of life) in the curve L and an approximate straight-line Lq in the part Q at the end of driving (end of life) in the curve L, an intersection point of these approximate straight-lines is defined as an inflection point P.

Then, an experiment of measuring a time necessary to reach the inflection point P was performed at an environmental temperature of 90° C. at different doping concentrations of Ba and Yb as a metal dopant of the second functional layer 19 (acceleration test). In this experiment, samples of organic EL elements having the same structure as the layered structure of the subpixels R in FIG. 6 were used.

FIG. 7B is a table illustrating results of the experiment. In the table, column “inflection point (h)” indicates a time necessary to reach the inflection point P since start of driving the organic EL elements (inflection point arrival time). Also, column “inflection point (relative value)” indicates a relative value in % of the inflection point arrival time under various conditions in the case where an inflection point arrival time of Ba as the metal dopant at the doping concentration of 40 wt % was set to “1”.

As illustrated in the table of FIG. 7B, in the case where Ba was used as the metal dopant of the second functional layer 19, the inflection point arrival time reached only 220 hours even at its maximum doping concentration of 40 wt %. Meanwhile, in the case where Yb was used as the metal dopant, the inflection point arrival time already reached 210 hours at its doping concentration of 20 wt %, and reached 400 hours at its doping concentration of 40 wt %, which is larger by 182% than the case where the metal dopant was Ba.

As illustrated in FIG. 7A, until the inflection point arrival time has passed by, variation of the driving voltage was relatively gradual. Accordingly, the results of the experiment indicate that as the inflection point arrival time increases, a degree of deterioration of electron injection properties of the metal dopant decreases. It is assessed that the larger the inflection point arrival time is, the more stable the electron injection properties are.

Thus, by adopting Yb as the metal dopant of the second functional layer 19, the electron injection properties are much more stabilized than conventional cases where Ba is used as the metal dopant. This suppresses variation in driving voltage between the light emission colors due to the difference in film thickness of the first functional layers 22 and the organic light-emitting layers 17 in the optical cavity structure between the light emission colors, thereby suppressing deterioration in image quality to prolong the product operating life.

5. Method of Manufacturing Display Panel

The following describes a method of manufacturing the display panel 10 pertaining to at least one aspect of the present disclosure, with reference to the drawings.

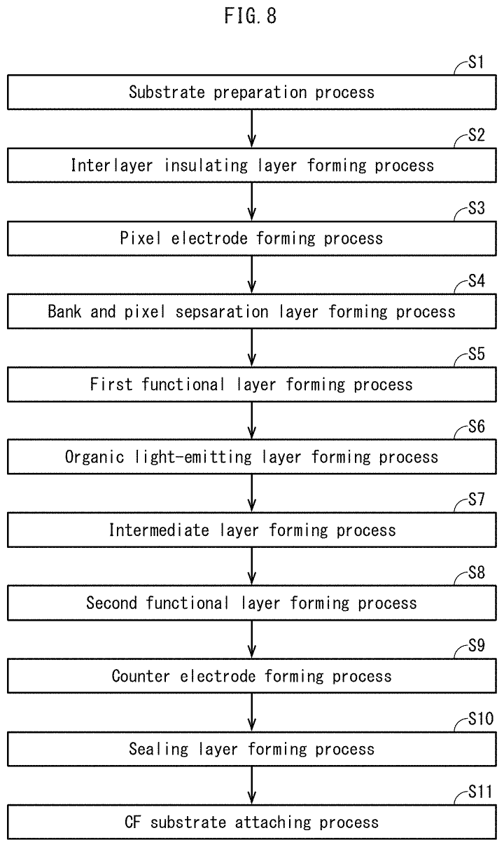

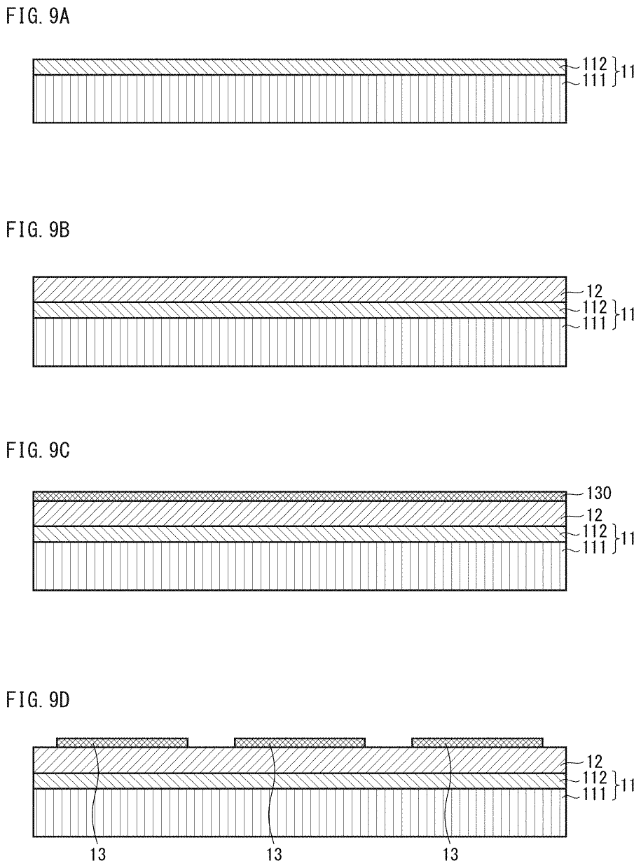

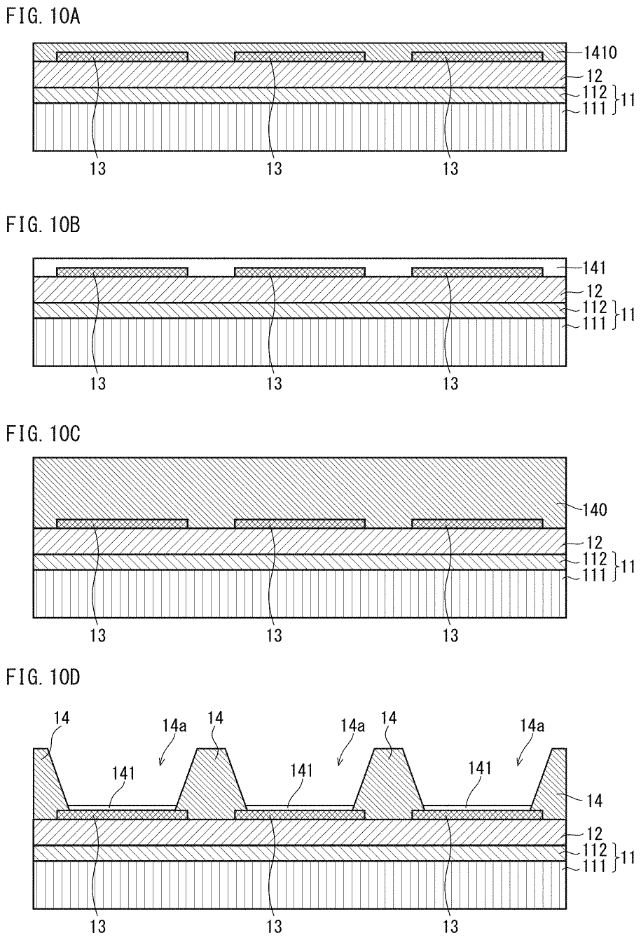

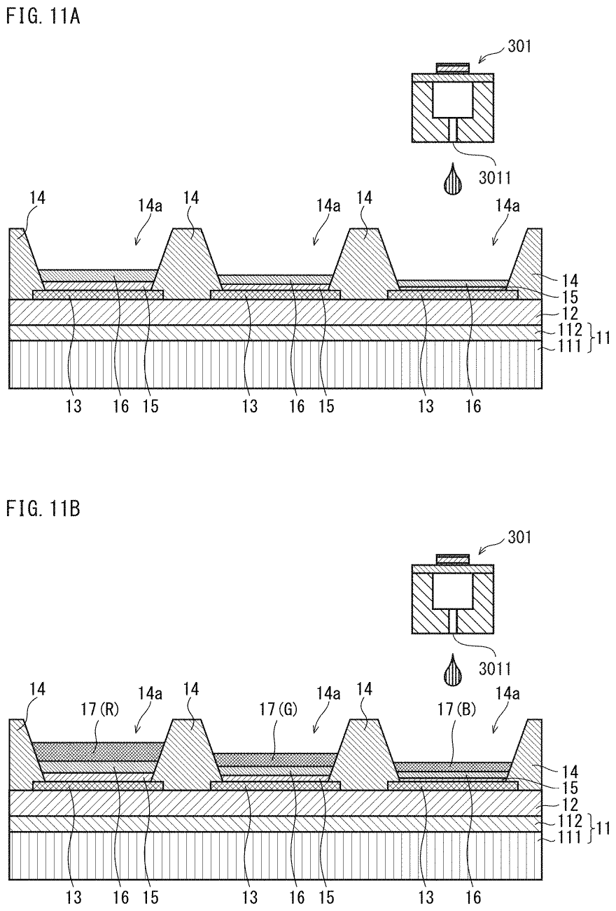

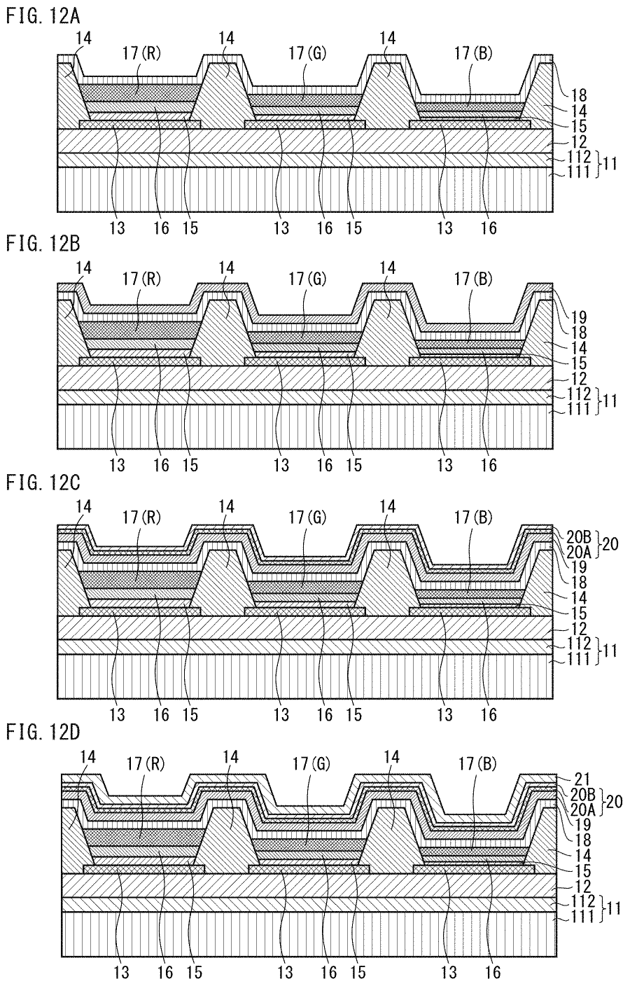

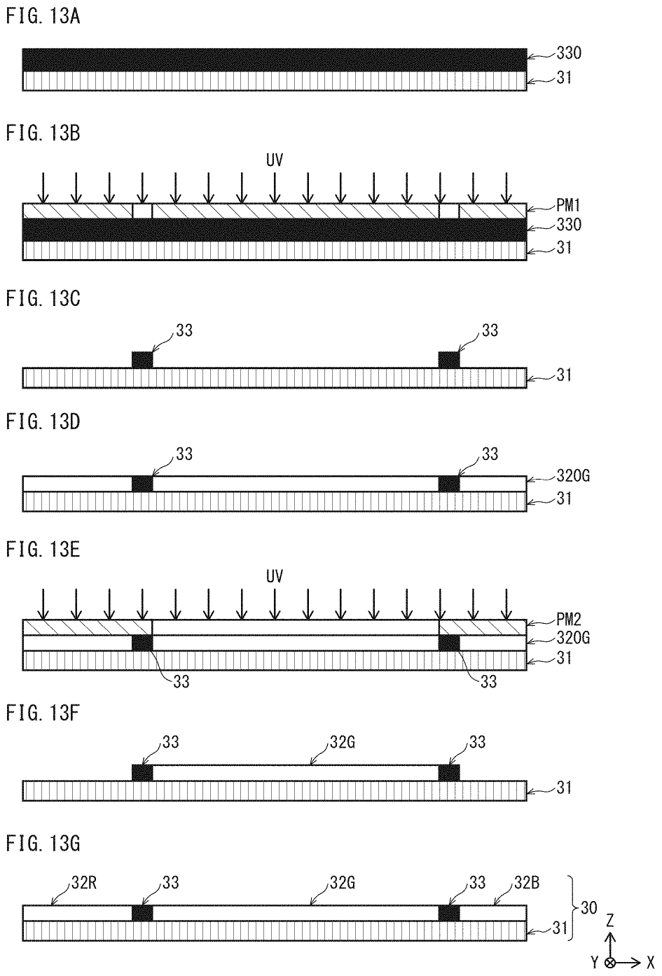

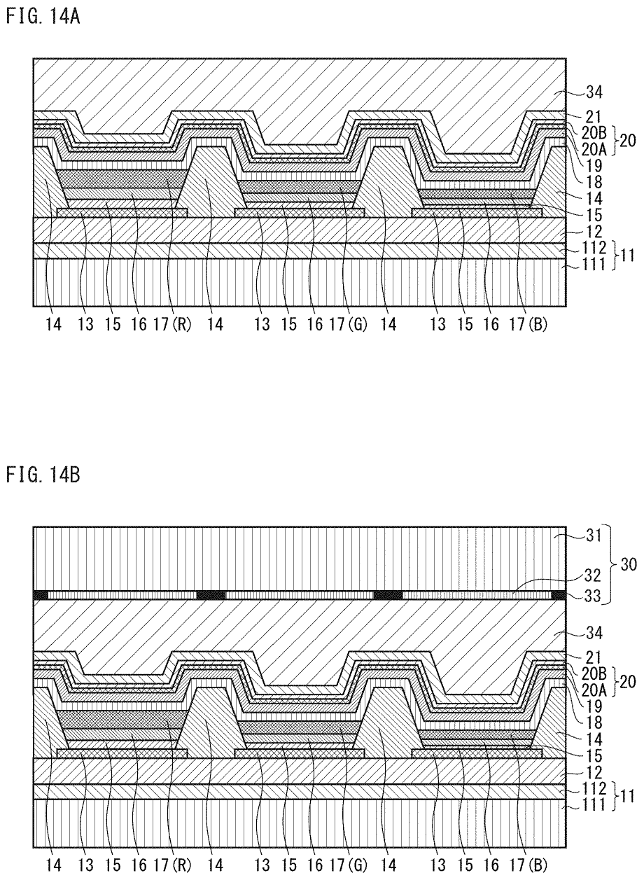

FIG. 8 is a flowchart illustrating a manufacturing process of the display panel 10. FIG. 9A to FIG. 9D, FIG. 10A to FIG. 10D, FIG. 11A, FIG. 11B, FIG. 12A to FIG. 12D, FIG. 13A to FIG. 13G, FIG. 14A, and FIG. 14B are schematic cross-section diagrams illustrating processes in manufacturing the display panel 10.

(1) Substrate Preparing Process

First, as illustrated in FIG. 9A, a substrate 11 is prepared by forming a TFT layer 112 on a base material 111 (FIG. 8: Step S1). The TFT layer 112 can be formed by a known TFT manufacturing method.

(2) Interlayer Insulating Layer Forming Process

Next, as illustrated in FIG. 9B, an interlayer insulating layer 12 is formed on the substrate 11 (FIG. 8: Step S2).

Specifically, a resin material having a constant fluidity is applied across a top surface of the substrate 11 by for example die coating so as to fill irregularities in the substrate 11 caused by the TFT layer 112. Thus, a top surface of the interlayer insulating layer 12 has a flattened shape conforming to a top surface of the base material 111.

Also, dry-etching is performed on parts of the interlayer insulating layer 12 above TFT elements, for example source electrodes, to provide contact holes (not illustrated). The contact holes are provided by patterning or the like such that surfaces of the source electrodes are exposed at bottoms of the contact holes.

Next, connection electrode layers are formed along inner walls of the contact holes. Upper parts of the connection electrode layers are partially disposed on the interlayer insulating layer 12. The connection electrode layers can be formed by forming a metal film by for example sputtering, and then patterning the metal film by photolithography and wet etching.

(3) Pixel Electrode Forming Process

Next, as illustrated in FIG. 9C, a pixel electrode material layer 130 is formed on the interlayer insulating layer 12. The pixel electrode material layer 130 can be formed by vacuum deposition, sputtering, or the like.

Then, as illustrated in FIG. 9D, the pixel electrode material layer 130 is patterned by etching to form a plurality of pixel electrodes 13 partitioned for each subpixel (FIG. 8: Step S3).

(4) Bank and Pixel Partition Layer Forming Process

Next, banks 14 and pixel partition layers 141 are formed (FIG. 8: Step S4).

In the present embodiment, the pixel partition layers 141 and the banks 14 are formed through separate processes.

(4-1) Pixel Partition Layer Formation

First, the pixel partition layers 141 extending in the X direction are formed so as to partition pixel electrode columns extending in the Y direction (FIG. 2) for each subpixel.

As illustrated in FIG. 10A, a pixel partition layer material layer 1410 is formed by uniformly applying a photosensitive resin material which is a material of the pixel partition layers 141 onto the interlayer insulating layer 12 on which the pixel electrodes 13 are formed. Here, an application amount of the resin material has been determined in advance such that the pixel partition layer material layer 1410 after drying has a desired film thickness of the pixel partition layers 141.

A method of applying the resin material is specifically for example a wet process such as die coating, slit coating, and spin coating. In at least one embodiment, by for example vacuum drying and low-temperature heating at an approximate temperature of 60° C. to 120° C. (pre-baking) after application, an unnecessary solvent is removed, and also the pixel partition layer material layer 1410 is fixed onto the interlayer insulating layer 12.

Then, the pixel partition layer material layer 1410 is patterned by photolithography.

For example, in the case where the pixel partition layer material layer 1410 has positive photosensitivity, exposure is performed on the pixel partition layer material layer 1410 via a photomask (not illustrated). The photomask shields parts of the pixel partition layer material layer 1410 to remain as the pixel partition layers 141 against light and has light-transmissive parts corresponding to parts of the pixel partition layer material layer 1410 to be removed.

Next, developing is performed, and the exposed parts of the pixel partition layer material layer 1410 are removed. Thus, the pixel partition layers 141 are formed. Specific examples of developing methods include a method of immersing the entire substrate 11 in a developer such as an organic solvent and an alkali solution which dissolves parts of the pixel partition layer material layer 1410 which have been exposed to light, and then rinsing the substrate 11 by a rinse solution such as pure water.

Then, the pixel partition layer material layer 1410 is baked (post-baked) at a predefined temperature. As a result, the pixel partition layers 141 extending in the X direction are formed on the interlayer insulating layer 12 (FIG. 10B).

(4-2) Bank Formation

Next, the banks 14 extending in the Y direction are formed in the same manner as the pixel partition layers 141 described above.

Specifically, a bank material layer 140 is formed by applying a resin material for banks by die coating or the like onto the interlayer insulating layer 12, on which the pixel electrodes 13 and the pixel partition layers 141 are formed (FIG. 10C). Here, an application amount of the resin material has been determined in advance such that the bank material layer 140 after drying has a desired height of the banks 14.

Then, the bank material layer 140 is patterned to make the banks 14 extending in the Y direction by photolithography and is baked at a predefined temperature, completing the banks 14 (FIG. 10D).

In the above process, the respective material layers for the pixel partition layers 141 and the banks 14 are both formed by a wet process and then are patterned. In at least one embodiment, at least one of the respective material layers for the pixel partition layers 141 and the banks 14 is formed by a dry process and then is patterned by photolithography and etching.

(5) First Functional Layer Forming Process

A first functional layer forming process includes formation of hole injection layers 15 and formation of hole transport layers 16 (FIG. 8: Step S5).

First, the hole injection layers 15 are formed by ejecting ink containing an electrically-conductive polymer material such as poly(3,4-ethylenedioxythiophene) polystyrene sulfonate (PEDOT/PSS) from nozzles 3011 of an application head 301 of a printing device to apply the ink into openings 14a, volatizing and removing solvent, and/or baking the solvent.

Then, the hole transport layers 16 are formed by applying ink containing material of the hole transport layers 16 onto the hole injection layers 15, volatizing and removing solvent, and/or baking the solvent. The material of the hole transport layers 16 is for example a high-molecular compound having no hydrophilic group such as polyfluorene, polyfluorene derivative, polyallylamine, and polyallylamine derivative. A method of applying the material is the same as in the case of the hole injection layers 15.

FIG. 11A is a cross-section diagram illustrating the display panel 10 in the forming process of the hole transport layers 16 after the forming process of the hole injection layers 15. Note that the hole injection layers 15 and the hole transport layers 16 have the respective film thicknesses such as illustrated in the table in FIG. 6 by ink application with ink amounts (or both the ink amounts and ink densities) which differ between the light emission colors.

(6) Organic Light-Emitting Layer Forming Process

Next, organic light-emitting layers 17 are formed above the hole transport layers 16 (FIG. 8: Step S6).

Specifically, as illustrated in FIG. 11B, ink containing a light-emitting material of a corresponding light emission color is sequentially ejected from the nozzles 3011 of the application head 301 of the printing device into the openings 14a onto the hole transport layers 16 in the openings 14a.

Then, the substrate 11 after ink application is carried into a vacuum dry chamber and is heated in a vacuum, thereby evaporating an organic solvent in the ink. Thus, the organic light-emitting layers 17 are formed.

Note that the organic light-emitting layers 17 have the film thicknesses such as illustrated in the table in FIG. 6 by ink application with ink amounts (or both the ink amounts and ink densities) which differ between the light emission colors.

(7) Intermediate Layer Forming Process

Next, as illustrated in FIG. 12A, an intermediate layer 18 is formed on the organic light-emitting layers 17 and the banks 14 (FIG. 8: Step S7). The intermediate layer 18 is formed by forming a film of NaF across all the subpixels by vapor deposition.

(8) Second Functional Layer Forming Process

Next, as illustrated in FIG. 12B, the second functional layer 19 is formed on the intermediate layer 18 (FIG. 8: Step S8). The second functional layer 19 is formed by for example forming a film by co-deposition using an organic material having electron transport properties and Yb as a metal dopant across all the subpixels.

In the present embodiment, a doping concentration of Yb is set to 20 wt %.

(9) Counter Electrode Forming Process

Next, a counter electrode 20 is formed on the second functional layer 19 (FIG. 8: Step S9).

In a counter electrode forming process, a light-transmissive and electrically-conductive film (IZO film) 20A is firstly formed on the second functional layer 19 by sputtering, and then a metal thin film 20B is formed on the light-transmissive and electrically-conductive film (IZO film) 20A by forming a film of silver, aluminum, or the like by sputtering, vacuum deposition, or the like (FIG. 12C).

(10) Sealing Layer Forming Process

Next, as illustrated in FIG. 12D, a sealing layer 21 is formed on the counter electrode 20 (FIG. 8: Step S10). The sealing layer 21 can be formed by forming a film of SiON, SiN, or the like by sputtering, CVD, or the like.

(11) CF Substrate Attaching Process

Next, a CF substrate 30 is formed and is attached onto the sealing layer 21 (FIG. 8: Step S11).

FIG. 13A to FIG. 13G are schematic cross-section diagrams illustrating a process of manufacturing the CF substrate 30.

First, a light-transmissive upper substrate 31 is prepared, and a material of light shielding layers 33 that is primarily an ultraviolet curable resin (for example, ultraviolet curable acrylic resin) material to which a black pigment is added, is applied on one surface of the upper substrate 31, thereby obtaining a light-shielding layer material layer 330 (FIG. 13A).

A pattern mask PM1 having predefined openings is overlaid on a top surface of the light-shielding layer material layer 330 and is irradiated from above with ultraviolet light (FIG. 13B).

Then, the pattern mask PM1 and uncured parts of the light-shielding layer material layer 330 are removed, developing is performed, and then curing is performed, Thus, the light-shielding layers 33 are completed and each have for example a substantially rectangular shape in cross-section (FIG. 13C).

Next, a paste 320G containing material of a color filter, for example a green (G) color filter, that is primarily an ultraviolet curable resin component is applied to a surface of the upper substrate 31 on which the light-shielding layers 33 are formed (FIG. 13D). Then, a predefined pattern mask PM2 is placed, and ultraviolet irradiation is performed (FIG. 13E).

Subsequently, curing is performed, the pattern mask PM2 and uncured parts of the paste 320G are removed, and developing is performed. Thus, a color filter layer 32G is formed (FIG. 13F).

This process illustrated in FIG. 13D to FIG. 13F is repeated similarly for each of pastes of red (R) and blue (B) color filters to form color filter layers 32(R) and 32(B) (FIG. 13G).

In at least one embodiment, commercially available color filter products are used, instead of using pastes of the R, G, and B colors. Thus, the CF substrate 30 is formed.

Next, a material of a joining layer 34 that is primarily an ultraviolet curable resin such as acrylic resin, silicone resin, and epoxy resin is applied to a panel main body which includes every layer from the substrate 11 to the sealing layer 21 (FIG. 14A).

Next, the applied material of the joining layer 34 is irradiated with ultraviolet light, and the panel main body and the CF substrate 30 are joined to each other while matching positions relative to each other. No gas should enter between the panel main body and the CF substrate 30 at this time. Then, the panel main body and the CF substrate 30 are baked and thus a sealing process is completed, completing the display panel 10 (FIG. 14B).

Note that the above manufacturing method is just an example and can be appropriately modified according to the spirit of the present disclosure.

Further, in at least one embodiment, the CF substrate manufacturing process has been performed in advance.

<<Modifications>>

Embodiments of an organic EL display panel, an organic EL element manufacturing method, and so on have been described as aspects of the present disclosure, but the present disclosure is not limited to the description above beyond essential characteristic elements thereof. The following describes other aspects of the present disclosure as modifications.

(1) Intermediate Layer and Second Functional Layer

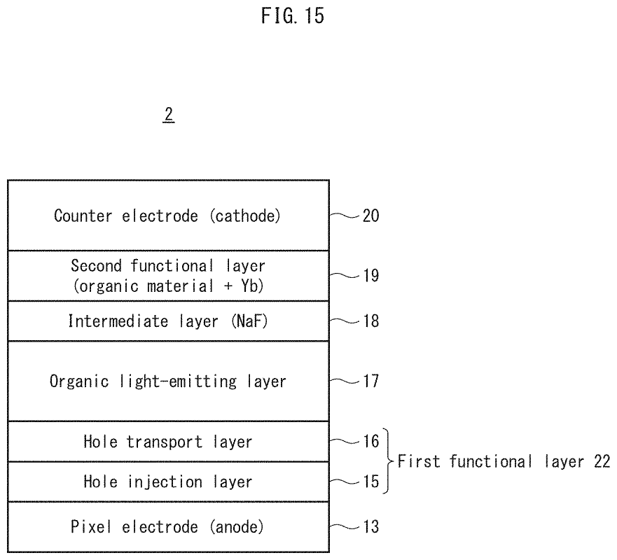

(A) In at least one embodiment, the organic EL elements each include a main part (part from the anode to the cathode, hereinafter referred to also as light-emitting part) which has a layered structure such as illustrated in the schematic diagram in FIG. 15.

The intermediate layer 18 includes NaF, but the present disclosure is not limited to this. The intermediate layer 18 may include a fluoride of a metal selected from other alkali metals or alkaline earth metals. This is because the fluoride of the selected metal has similar properties of blocking moisture etc., and the metal belonging to these groups exhibits electron injection properties when part of the fluoride of metal is reduced by Yb.

In at least one embodiment, the second functional layer 19 includes an organic material having electron transport properties which is doped with Yb at a doping concentration of 20 wt %. However, the present disclosure is not limited to this. The doping concentration of Yb may range from 3 wt % to 60 wt %.

As described above, since Yb is a substance which is chemically stable and hardly reacts with moisture etc. compared with Ba and the like, Yb doping even at the doping concentration of 3 wt % can sufficiently exhibit its electron injection properties.

Also, since Yb has an excellent light-transmissivity compared with Ba and the like, Yb doping even at the maximum doping concentration of 60 wt % does not have a significant influence on a transmittance of the second functional layer 19, and an excellent luminous efficiency can be maintained.

Yb doping at a high doping concentration can be performed in this way. This helps to maintain the electron injection properties further stably for a long period, thereby contributing to a further increase in operating life. Also, since the range of the Yb doping concentration is wide, it is considered that the organic material as the host material of the second functional layer 19 accordingly can be set to have a film thickness which ranges widely, thereby increasing a degree of freedom in designing optical cavity structure.

Also, the counter electrode 20 pertaining to at least one embodiment has a two-layer structure including the light-transmissive and electrically-conductive film (IZO film) 20A and the metal thin film 20B. However, in the case where an optical path length necessary to construct an optical cavity structure can be provided by varying thickness of other layer, the light-transmissive and electrically-conductive film (IZO film) 20A is not necessarily essential.

Further, instead of an IZO film, an ITO film which is a light-transmissive and electrically-conductive material including metal oxide likewise, may be used.

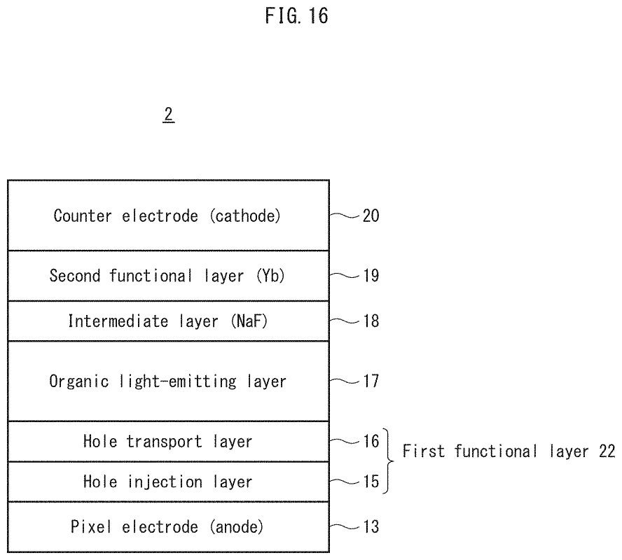

(B) Also, in at least one embodiment, the second functional layer 19 is formed by doping an organic material with Yb, but the present disclosure is not limited to this. The second functional layer 19 may be a single Yb layer as illustrated in FIG. 16.

With this structure, the single Yb layer has a further increased liquid resistance and also has an increased Yb effective contact area with NaF of the intermediate layer 18, compared with the layer of the organic material doped with Yb. This promotes a reduction action of NaF by Yb, thereby helping to Na obtained by dissociation to improve the electron injection properties.

In this case, the second functional layer 19 is formed by forming a Yb film on the intermediate layer 18 by vapor deposition or sputtering.

In at least one embodiment, the single Yb layer has a film thickness from 0.1 nm to 10 nm. This is because the single Yb layer having a film thickness smaller than 0.1 nm might exhibit insufficient electron injection properties, while the single Yb layer having a film thickness larger than 10 nm causes a problem in light-transmissivity and thus might exhibit a deteriorated luminous efficiency.

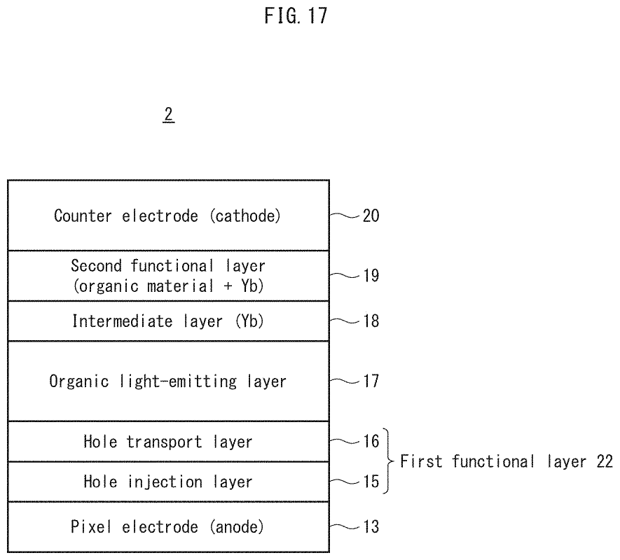

(C) Also, the intermediate layer 18 may be a single Yb layer as illustrated in FIG. 17 instead of an NaF single layer. As described above, since Yb hardly reacts with moisture etc. and has liquid resistance, and thus can sufficiently serve as a block against moisture etc. Further, the Yb layer is in direct contact with the entire surface of the organic light-emitting layers 17, and thus can exhibit high electron injection properties.

The intermediate layer 18 in this case has a film thickness preferably from 0.1 nm to 10 nm. This is because the single Yb layer having a film thickness smaller than 0.1 nm might exhibit insufficient properties of blocking moisture etc. and insufficient electron injection properties, while the single Yb layer having a film thickness larger than 10 nm causes a problem in light-transmissivity and thus might exhibit a deteriorated luminous efficiency.

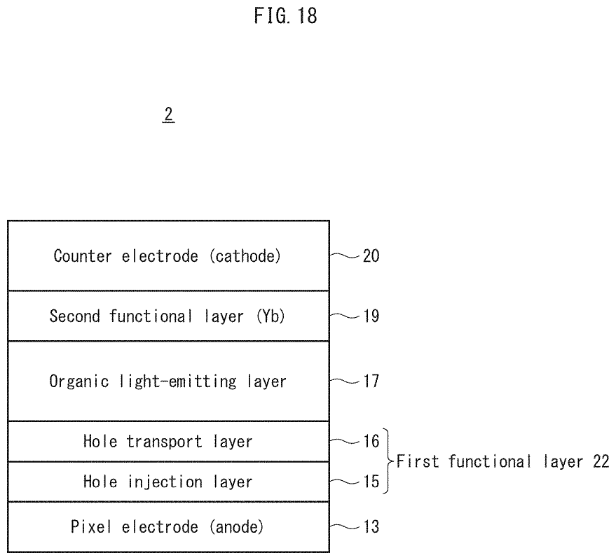

(D) The stability of Yb is high as described above. Accordingly, the intermediate layer 18 does not need to be provided and the second functional layer 19 may include a single Yb layer such as illustrated in FIG. 18. It is considered that this causes the entire surface of Yb atoms to contact the counter electrode 20 and the organic light-emitting layers 17, thereby increasing the stability of the electron injection properties.

The second functional layer 19 in this case has a film thickness preferably from 0.1 nm to 10 nm. This is because the single Yb layer having a film thickness smaller than 0.1 nm might exhibit insufficient properties of blocking moisture etc. and insufficient electron injection properties, while the single Yb layer having a film thickness larger than 10 nm causes a problem in light-transmissivity and thus might exhibit a deteriorated luminous efficiency.

According to the present modification, the intermediate layer 18 can be omitted and thus the manufacturing process can be simplified.

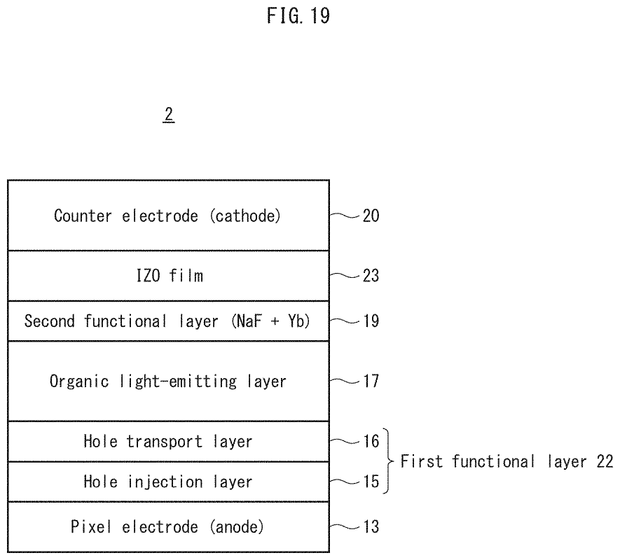

(E) Also, the intermediate layer 18 does not need to be provided and the second functional layer 19 may include a mixture of NaF and Yb as illustrated in FIG. 19.

This second functional layer 19 is formed by for example co-deposition of NaF and Yb on the organic light-emitting layers 17.

With this structure, the second functional layer 19 itself has the electron injection properties exhibited by Yb and the properties of blocking moisture etc. which are the inherent function of the intermediate layer 18, and atoms of NaF and Yb are mixed together dispersedly in one layer, thereby achieving effects as follows.

Specifically, in the case where the second functional layer 19 (single Yb layer) is layered on the intermediate layer 18 (NaF) such as illustrated in FIG. 16, a reduction action of NaF by Yb exerts on only a contact part of the intermediate layer 18 which is in contact with the second functional layer 19. Accordingly, an increase in film thickness of the intermediate layer 18 further promotes an increase in driving voltage. Thus, the purpose of improving the luminous efficiency might be insufficiently achieved.

According to the present modification, however, since the single second functional layer 19 includes NaF and Yb which are mixed together by co-deposition, reduction of NaF by Yb exerts on even an inner part of the layer. Accordingly, even when the film thickness of the second functional layer 19 is increased to a certain extent, the electron injection properties are unlikely to decrease, and thus the second functional layer 19 serves a layer for adjusting an optical distance in an optical cavity structure. This eliminates the need to provide any other special film thickness adjustment layer, thereby simplifying the manufacturing process to reduce the production cost, and also constructing the optical cavity structure to seek an improvement in luminous efficiency.

In the present modification, a ratio (wt %) of a weight of Yb to a total weight of NaF and Yb preferably ranges from larger than 73 wt % and smaller than 100 wt %, and the film thickness of the second functional layer 19 is preferably 10 nm or larger and smaller than 20 nm.

Further, in the present modification, a light-transmissive and electrically-conductive film which includes metal oxide such as an IZO film and an ITO film is preferably formed on the second functional layer 19 (however, such a film is not necessary to be newly provided in the case where the counter electrode 20 originally includes the light-transmissive and electrically-conductive film (IZO film) 20A such as in the above embodiment).

In the present modification, the IZO film 23 is formed by sputtering.

Rare earth metal such as Yb typically has the following characteristics. When rare earth metal is oxidized, light-transmissivity is improved. Meanwhile, when single rare earth metal is oxidized, an oxide (passivity) is formed on only a surface of the single rare earth metal. Due to blocking by the oxide, which is formed densely on the rare earth metal, Yb atoms in a further inner part of a layer is not oxidized. According to the present modification, however, since NaF and Yb are co-deposited and Yb atoms and NaF molecules are dispersedly present as a mixture, the Yb atoms (Yb clusters) have gaps therebetween. Sputtering IZO on the mixture, not only the Yb atoms on the surface are oxidized, but also IZO intrudes through the gaps between the Yb atoms and thus the Yb atoms in the inside are successively oxidized. This helps to oxidization of even Yb atoms which are present at a significantly depth in the film thickness direction, thereby remarkably improving a transmittance.

(2) Other Modifications of Layered Structure of Organic EL Elements

In at least one embodiment, the first functional layers 22 each include two layers, namely, the hole injection layer 15 and the hole transport layer 16. However, the present disclosure is not limited to this. The first functional layer 22 may include either one of the hole injection layer 15 and the hole transport layer 16, or may be a hole injection transport layer including a material having characteristics of both the hole injection layers 15 and the hole transport layers 16.

Also, an electron injection layer may be separately added between the second functional layer 19 and the counter electrode 20.

Further, instead of the CF substrate 30, a polarizing filter substrate may be provided so as to improve antiglare properties.

(3) Modification of Bank and Pixel Partition Layer Forming Process

In at least one embodiment, the banks 14 and the pixel partition layers 141 are formed in separate processes. However, the present disclosure is not limited to this. The banks 14 and the pixel partition layers 141 may be simultaneously formed by using a halftone mask, as follows.

First, the bank material layer 140 is formed by applying a resin material by a wet process such as die coating onto the interlayer insulating layer 12, on which the pixel electrodes 13 and the pixel partition layers 141 are formed (see FIG. 10C).

It is preferable that for example, by for example vacuum drying and low-temperature heating at an approximate temperature of 60° C. to 120° C. (pre-baking) after application, an unnecessary solvent is removed, and also the bank material layer is fixed onto the interlayer insulating layer 12.

Next, exposure is performed on the bank material layer 140 via a photomask (not illustrated).

For example, in the case where the bank material layer 140 has positive photosensitivity, parts of the bank material layer 140 to remain are shielded against light, and exposure is performed on parts of the bank material layer 140 to be removed.

Since the pixel partition layers 141 have a smaller film thickness than the banks 14, half-exposure needs to be performed on parts of the bank material layer 140 which are to remain as the pixel partition layers 141.

For this reason, as a photomask for use in an exposure process, a halftone mask having the following parts is used: light-shielding parts which are provided in positions corresponding to the banks 14 and completely shield against light; light-semitransmissive parts which are provided in positions corresponding to the pixel partition layers 141; and light-transmissive parts which are provided in positions corresponding to exposed parts of the pixel electrodes 13 other than the banks 14 and the pixel partition layers 141.

Transmittancy of the light-semitransmissive parts is determined such that exposure for a predefined period makes the bank material layer 140 on the pixel electrodes 13 to be fully exposed and makes parts of the bank material layer 140 as the pixel partition layers 141 to remain unexposed by a height thereof.

Next, developing is performed, and the exposed parts of the bank material layer 140 are removed. Thus, the banks 14 and the pixel partition layers 141 which have a smaller film thickness than the banks 14 are formed. Specific examples of developing methods include a method of immersing the entire substrate 11 in a developer such as an organic solvent and an alkaline solution which dissolves portions of the bank material layer 140 which have been exposed to light, and then rinsing the substrate 11 by a rinse solution such as pure water. Then, the bank material layer 140 is baked at a predefined temperature.

As described above, the use of a halftone mask helps to form, on the interlayer insulating layer 12, the banks 14 extending in the Y direction and the pixel partition layers 141 extending in the X direction by the same process, thereby reducing the number of processes accordingly. This contributes to cost reduction of organic EL display panel manufacturing.

(4) Modification for Banks Having Multi-Layer Structure

As described above, in the case where the first functional layers 22, the organic light-emitting layers 17, and the like are formed for constructing an optical cavity structure by a printing method such that these layers each have a different film thickness between the light emission colors, these layers sometimes have film shapes (especially, profiles of the surfaces in the cross-sections) slightly differing depending on an ink application amount.

Typically, when an ink is dropped in the openings 14a (see FIG. 3) between the adjacent banks 14, liquid surfaces of parts (pinning) of the ink which are in contact with the banks 14 are higher than liquid surfaces of central parts of the ink in the openings 14a. After drying the ink in this state as it is, a thickness of parts near the banks 14 tends to be larger than a thickness of the central parts. In particular, due to the organic light-emitting layers having a higher electrical resistivity than other organic functional layers, an electric current might concentrate in the central parts having a smaller film thickness to shorten the operating life of the light-emitting elements, and the film shape is not stable and thus constructing an optical cavity structure is difficult.

According to the present modification, in view of this problem, the banks 14 have a multi-layer structure so as to uniformize a film shape of organic layers formed by a printing method.

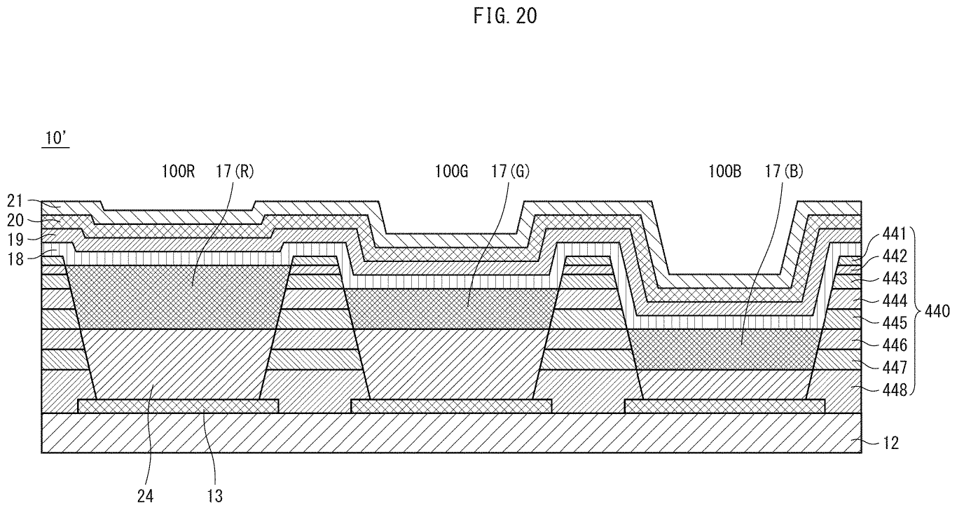

FIG. 20 is a schematic cross-section diagram illustrating a structure of a display panel 10′ pertaining to the present modification. In the figure, numerical reference the same as in FIG. 4 represent structure elements the same as in FIG. 4, and accordingly description thereof is omitted. In addition, a substrate 11, a CF substrate 30, and so on are not illustrated.

As illustrated in FIG. 20, the display panel 10′ includes light-emitting parts each of which is formed by layering a pixel electrode 13, a hole injection transport layer 24, an organic light-emitting layer 17 (17(R), 17(G), or 17(B)), an intermediate layer 18, a second functional layer 19, a counter electrode 20, and a sealing layer 21 in this order. The hole injection transport layer 24 and the organic light-emitting layer 17 are formed by a printing method.

In addition, in the present modification, banks 440 have a multi-layer structure including a first layer 441 to an eighth layer 448. Among these layers, the odd ordinal numbered layers 441, 443, 445, and 447 include a material having a higher liquid repellency than the even ordinal numbered layers 442, 444, 446, and 448 include.

With this structure, for example when an ink of amount necessary to form an applied film having a target film thickness as the hole injection transport layer 24 in a subpixel 100B is dropped, parts (pinning position) of liquid surfaces of the ink which are in contact with the banks 440 are not in contact with the seventh layer 447, which has a higher liquid repellency, and remain at a border between the seventh layer 447 and the eighth layer 448, which has a lower liquid repellency. Accordingly, adjustment of the ink amount to be dropped allows to obtain the hole injection transport layer 24 which has a surface whose height is substantially equal to a height of the border between the seventh layer 447 and the eighth layer 448 and has a uniform film thickness.

To increase the film thickness of the hole injection transport layer 24 such as in a subpixel 100G, pining is positioned at a border between the fifth layer 445 and the sixth layer 446. Accordingly, by adjusting the ink amount so as to reach the height of the border, it is possible to obtain the hole injection transport layer 24 in the subpixel 100G with a substantially uniform film thickness which is larger than the film thickness of the hole injection transport layer 24 in the subpixel 100B by the total film thickness of the sixth layer 446 and the seventh layer 447 in the subpixel 100B.

Such a method helps to form the hole injection transport layers 24 and the organic light-emitting layers 17 having substantially uniform film thicknesses corresponding to the light emission colors.

Note that FIG. 20 is just a schematic diagram. In practice, film thicknesses of layers for effectively obtaining an optical cavity structure are determined by design, and the number of layers to be included in the banks 440 and film thicknesses of the layers are set in accordance with the determined film thicknesses. This achieves a display panel having a further excellent luminous efficiency.

(5) According to the display panel 10 pertaining to at least one embodiment, as illustrated in FIG. 2, the pixel partition layers 141 extend in the long-axis X direction of the display panel 10 and the banks 14 extend in the short-axis Y direction of the display panel 10. However, the present disclosure is not limited to this. The extending directions of the pixel partition layers 141 and the banks 14 may be reversed. Alternatively, the extending directions of the pixel partition layers 141 and the banks 14 may be directions independent of the shape of the display panel 10.

Also, according to the display panel 10 pertaining to at least one embodiment, the image display surface has a rectangular shape as an example. However, the shape of the image display surface is not limited to this and may be modified as appropriate.

Further, according to the display panel 10 pertaining to at least one embodiment, the pixel electrodes 13 are rectangular plate-like members. However, the present disclosure is not limited to this.

Moreover, in at least one embodiment, the description has been provided on an organic EL display panel employing the line bank structure. However, the present disclosure is not limited to this and may be an organic EL display panel employing a so-called pixel bank structure in which all sides of each subpixel are surrounded by banks.

However, when the line bank structure is employed, an effect of adopting Yb having liquid resistance as a metal dopant of the second functional layer 19 is exhibited further greatly, compared with the pixel bank structure. This is because according to the line bank structure, the light-emitting layers are formed even on the pixel partition layers 141 and thus a larger amount of ink is dropped and a larger amount of moisture etc. remains after drying, compared with the pixel bank structure.

Also, the organic EL elements (light-emitting parts) only need to be two-dimensionally arranged above the substrate across the main surface of the substrate, and do not necessarily need to be arranged exactly in a matrix. For example, the subpixels each having a regular hexagonal shape in plan view may be arranged in a honeycomb structure.

(6) In at least one embodiment, the hole injection layers 15, the hole transport layers 16, and the organic light-emitting layers 17 are all formed by a printing method (application method) such that the thickness differs between the R, G, and B colors. However, the present disclosure is not limited to this. Only one layer among these layers may be an applied film which is formed by a printing method, in accordance with a target optical cavity structure. Note that whether a certain layer in a finished product of the display panel 10 is an applied film or not can be easily determined by detecting moisture or solvent remaining in the layer.

(7) In the display panel 10 pertaining to at least one embodiment, the subpixels 100R, 100G, and 100B, which emit light of the R, G, and B colors respectively, are arranged. However, the light emission colors of the subpixels are not limited to these and may be for example four colors including yellow (Y) color in addition to the R, G, and B colors. Also, the number of subpixels per color arranged in one pixel P is not limited to one, and may be plural. Further, the arrangement order of the subpixels in each pixel P is not limited to the red, green, and blue such as illustrated in FIG. 2, and the subpixels may be reordered among these colors.

(8) Adoption to Flexible Display Panel

A display panel achieves flexibility and sealing properties by including the base material 111 of the substrate 11 formed from a resin film and including the sealing layer 21 formed from two-layered thin films including an inorganic material which sandwich a resin material (organic film) therebetween. In such a display panel, adoption of Yb as a metal dopant of the second functional layer 19 such as in the above embodiment increases water resistance. Thus, durability of the sealing layer can be sufficiently achieved simply by layering one inorganic film and one organic film, thereby simplifying a sealing structure in a flexible display panel.

(9) Further, in at least one embodiment, the display panel 10 employs the active matrix system. However, the present disclosure is not limited to this, and a passive matrix system may be employed.

Moreover, the present disclosure is applicable not only to organic EL display panels of the top-emission type but also to organic EL display panels of a bottom-emission type.

In the case of the bottom-emission type, the counter electrode 20 is a light-reflective anode and the pixel electrodes 13 are cathodes including a light-transmissive material (including a light-semitransmissive material). In accordance with this, the layering order of other layers including the first functional layers 22, the intermediate layer 18, and the second functional layer 19 is different from that in the top-emission type.

Further, the base material 111 and the interlayer insulating layer 12 include a light-transmissive material. The drive circuits including TFTs in the TFT layer 112 are formed at positions overlapping the banks 14 and the pixel partition layers 141 in plan view so as not to shield against emitted light. Moreover, the CF substrate 30 may be attached onto the substrate 11 side. Alternatively, the CF substrate 30 itself may serves as the base material 111 of the substrate 11.

The present modification is generalized as follows. (a) One of a first electrode and a second electrode has light-reflectivity and the other has light-transmissivity; and thickness of a light-emitting layer and/or thickness of a functional layer disposed between the light-reflective electrode and the light-emitting layer differs between the first light-emitting part and the second light-emitting part which differs in light emission color from each other.

(b) The functional layer, which is disposed between the light-transmissive electrode and the light-emitting layer, includes ytterbium.

(c) The light-emitting layer and the functional layer, which is disposed between the light-emitting layer and the light-reflective electrode, include an applied film.

By satisfying the above requirements, the effects by the present disclosure can be achieved in common irrespective of the top-emission type or the bottom-emission type.

(10) In at least one embodiment, the structure is described in which one pixel includes three light-emitting parts (organic EL elements) which emit light of R, G, or B light emission color. However, the present disclosure is not limited to this, and one pixel may include two or four or more light-emitting parts in some cases.

Also, light-emitting parts included in one pixel do not necessarily differ in light emission color from each other. To achieve the effects by the present disclosure, it is only necessary that at least one of light-emitting parts included in one pixel differs in light emission color from any other of the light-emitting parts and that at least one of a light-emitting layer and a first functional layer included in the at least one light-emitting part differs in film thickness from that in the any other light-emitting part for the purpose of construction of an optical cavity structure.

(11) Description has been provided above of a method of manufacturing an organic EL display panel in which organic EL light-emitting layers are used. However, in addition to such organic EL display panels, display panels such as quantum dot display panels in which QLEDs are used as light-emitting layers (see, for example, Japanese Patent Application Publication No. 2010-199067) have a structure similar to organic EL display panels in which light-emitting layers and other functional layers are disposed between pixel electrodes and a counter electrode, although structures and types of the light-emitting layers are different. Accordingly, the present disclosure is applicable to formation of such display panels when an application method is used for forming the light-emitting layers and other functional layers.

### <<Supplement>>

Description has been provided above of display panels and display panel manufacturing methods pertaining to the present disclosure based on embodiments and modifications, but the present disclosure is not limited to the embodiments and modifications described above.

Although one or more embodiments pertaining to the present disclosure have been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. A display panel in which pixels each including light-emitting parts are two-dimensionally arranged across a main surface of a substrate, wherein
the light-emitting parts each comprise:
a first electrode that is light-reflective;
a first functional layer that is disposed above the first electrode;
a light-emitting layer that is disposed above the first functional layer;
a second functional layer that is disposed above the light-emitting layer and includes ytterbium; and
a second electrode that is disposed above the second functional layer and is light-transmissive,
at least one of the light-emitting layer and the first functional layer is an applied film,
with respect to each of the pixels, at least one of the light-emitting parts differs from any other of the light-emitting parts in terms of light emission color, and
the at least one light-emitting part differs from the any other of the light-emitting parts in terms of film thickness of at least one of the light-emitting layer and the first functional layer.

2. The display panel of claim 1, wherein
the light-emitting parts each further comprise
an intermediate layer that is disposed between the light-emitting layer and the second functional layer, and includes a fluoride of a metal selected from alkali metals or alkaline earth metals.

3. The display panel of claim 1, wherein
the light-emitting parts each further comprise
an intermediate layer that is disposed between the light-emitting layer and the second functional layer, and is a single ytterbium layer.

4. The display panel of claim 1, wherein
the second functional layer includes an organic material doped with ytterbium.

5. The display panel of claim 4, wherein
a doping concentration of the ytterbium ranges from 3 wt % to 60 wt %.

6. The display panel of claim 1, wherein
the second functional layer is a single ytterbium layer.

7. The display panel of claim 1, wherein
the second functional layer includes ytterbium and a fluoride of a metal selected from alkali metals or alkaline earth metals.

8. The display panel of claim 7, wherein
the light-emitting parts each further comprise
a light-transmissive and electrically-conductive film that is disposed between the second functional layer and the second electrode so as to be in contact with the second functional layer, and includes inorganic oxide.

9. The display panel of claim 8, wherein
the light-transmissive and electrically-conductive film is an indium tin oxide (ITO) film or an indium zinc oxide (IZO) film.

10. The display panel of claim 1, wherein
the first electrode is a light-reflective anode, and
the second electrode is a light-semitransmissive cathode.

11. A method of manufacturing a display panel in which pixels each including light-emitting parts are two-dimensionally arranged across a main surface of a substrate, the method comprising, for each of the light-emitting parts:
forming a first electrode above the substrate;
forming a first functional layer above the first electrode;
forming a light-emitting layer above the first functional layer;
forming a second functional layer above the light-emitting layer; and
forming a second electrode above the second functional layer, wherein
one of the first electrode and the second electrode is a light-reflective electrode, and the other is a light-transmissive electrode,
out of the first functional layer and the second functional layer, one functional layer that is disposed between the light-reflective electrode and the light-emitting layer includes ytterbium,
at least one of the light-emitting layer and the other functional layer out of the first functional layer and the second functional layer is formed by an application method,
with respect to each of the pixels, at least one of the light-emitting parts differs from any other of the light-emitting parts in terms of light emission color, and
the at least one light-emitting part differs from the any other of the light-emitting parts in terms of film thickness of at least one of the light-emitting layer and the other functional layer out of the first functional layer and the second functional layer.
